(19) United States
(12) Patent Application Publication
(10) Pub. No.: US 2025/0201639 A1
(43) Pub. Date: Jun. 19, 2025

(54) SEMICONDUCTOR DEVICE, MANUFACTURING METHOD THEREOF, AND ELECTRONIC APPARATUS

(71) Applicant: SONY SEMICONDUCTOR SOLUTIONS CORPORATION, KANAGAWA (JP)

(72) Inventors: HIROTAKA YOSHIOKA, KANAGAWA (JP); NOBUTOSHI FUJII, KANAGAWA (JP)

(21) Appl. No.: 18/848,868

(22) PCT Filed: Mar. 6, 2023
(86) PCT No.: PCT/JP2023/008222

§ 371 Date: Sep. 19, 2024

(30) Foreign Application Priority Data
Mar. 29, 2022 (JP) 2022-054574

(51) Int. Cl. H01L 21/66; H01L 23/00; H01L 25/16

(52) U.S. Cl. CPC H01L 22/32; H01L 22/12; H01L 24/05; H01L 24/08; H01L 24/80; H01L 25/167; H01L 2224/05554; H01L 2224/08145; H01L 2224/80895; H01L 2224/80896; H01L 2224/80908

(57) ABSTRACT

Provided is a semiconductor device capable of detecting joint misalignment between chips. A semiconductor device includes: a first semiconductor chip including a first region and a second region that is a region other than the first region on a first joint surface; and a second semiconductor chip in which one surface is a second joint surface, and the second joint surface is bonded to the first region. The first semiconductor chip includes a first sensing electrode facing the first region, a second sensing electrode surrounding the first sensing electrode, a first inspection electrode and a second inspection electrode facing the second region, a first connection wiring line electrically connecting the first sensing electrode to the first inspection electrode, and a second connection wiring line electrically connecting the second sensing electrode to the second inspection electrode, the second semiconductor chip includes a pad electrode facing the second joint surface and connected only to the first sensing electrode out of the first sensing electrode and the second sensing electrode, and a width of the pad electrode is smaller than a distance between portions of the second sensing electrode opposed to each other with the first sensing electrode interposed in between, and is larger than a distance between the first sensing electrode and the second sensing electrode.

### TECHNICAL FIELD

The present technology (technology according to the present disclosure) relates to a semiconductor device, a manufacturing method thereof, and an electronic apparatus, and particularly relates to a semiconductor device in which multiple semiconductor chips are bonded, a manufacturing method thereof, and an electronic apparatus.

### BACKGROUND ART

Conventionally, a semiconductor chip formed by bonding multiple chips is known. For example, Patent Document 1 discloses stacking chips on a transparent support substrate by a chip-on-wafer method.

### CITATION LIST

### Patent Document

Patent Document 1: WO 2013/179764 A

### SUMMARY OF THE INVENTION

### Problems to be Solved by the Invention

In a case where chips are stacked on a support substrate by a chip-on-wafer method, it has been difficult to detect joint misalignment of the chips in some cases. An object of the present technology is to provide a semiconductor device capable of detecting joint misalignment between chips (having a configuration capable of detecting joint misalignment), a manufacturing method thereof, and an electronic apparatus.

### Solutions to Problems

A semiconductor device according to an aspect of the present technology includes: a first semiconductor chip having one surface as a first joint surface and having a first region and a second region that is a region other than the above-described first region in the above-described first joint surface; and a second semiconductor chip in which a size in plan view is smaller than a size of the above-described first semiconductor chip, one surface is a second joint surface, and the above-described second joint surface is bonded to the above-described first region, in which the above-described first semiconductor chip includes a first sensing electrode facing the above-described first region, a second sensing electrode facing the above-described first region and surrounding the first sensing electrode, a first inspection electrode and a second inspection electrode facing the above-described second region, a first connection wiring line electrically connecting the above-described first sensing electrode to the above-described first inspection electrode, and a second connection wiring line electrically connecting the above-described second sensing electrode to the above-described second inspection electrode, the above-described second semiconductor chip includes a pad electrode facing the above-described second joint surface and connected only to the above-described first sensing electrode out of the above-described first sensing electrode and the above-described second sensing electrode, and a width of the above-described pad electrode is smaller than a distance between portions of the above-described second sensing electrode opposed to each other with the above-described first sensing electrode interposed in between, and is larger than a distance between the above-described first sensing electrode and the above-described second sensing electrode.

A manufacturing method for a semiconductor device according to an aspect of the present technology includes: preparing a semiconductor wafer including multiple chip regions that are regions to be divided into first semiconductor chips and having one surface as a first joint surface, and a second semiconductor chip having a size in plan view smaller than a size of each of the above-described chip regions and having one surface as a second joint surface, in which each of the above-described chip regions includes a first region in the above-described first joint surface, a second region in the above-described first joint surface other than the above-described first region, the first semiconductor chip includes a first sensing electrode facing the above-described first region, a second sensing electrode facing the above-described first region and surrounding the above-described first sensing electrode, a first inspection electrode and a second inspection electrode facing the above-described second region, a first connection wiring line electrically connecting the above-described first sensing electrode to the above-described first inspection electrode, and a second connection wiring line electrically connecting the above-described second sensing electrode to the above-described second inspection electrode, the above-described second semiconductor chip includes a pad electrode facing the above-described second joint surface, a width of the above-described pad electrode is smaller than a distance between portions of the above-described second sensing electrode opposed to each other with the above-described first sensing electrode interposed in between, and is larger than a distance between the above-described first sensing electrode and the above-described second sensing electrode; aligning the above-described second semiconductor chip and each of the above-described chip regions such that the above-described pad electrode and the above-described first sensing electrode overlap with each other; bonding the above-described second joint surface of the above-described second semiconductor chip to the above-described first region of each of the above-described chip regions; and determining whether or not joint between the above-described second semiconductor chip and each of the above-described chip regions is good on the basis of presence or absence of electrical conduction between the above-described first inspection electrode and the above-described second inspection electrode.

An electronic apparatus according to an aspect of the present technology includes the above-described semiconductor device and an optical system configured to form an image of image light from a subject on the above-described semiconductor device.

### BRIEF DESCRIPTION OF DRAWINGS

FIG. 1 is a chip layout diagram illustrating a configuration example of a photodetection device according to a first embodiment of the present technology.

FIG. 2 is a block diagram illustrating a configuration example of the photodetection device according to the first embodiment of the present technology.

FIG. 3 is an equivalent circuit diagram of pixels of the photodetection device according to the first embodiment of the present technology.

FIG. 4 is a longitudinal cross-sectional view illustrating a cross-sectional structure of the photodetection device according to the first embodiment of the present technology.

FIG. 5A is a plan view illustrating a planar configuration of a semiconductor wafer according to the first embodiment of the present technology.

FIG. 5B is an enlarged plan view illustrating a configuration of a chip region in a C region in FIG. 5A.

FIG. 5C is a plan view illustrating a planar configuration of the chip region of FIG. 5B.

FIG. 6A is a plan view illustrating a positional relationship between a pad electrode and a sensing electrode included in the photodetection device according to the first embodiment of the present technology.

FIG. 6B is a longitudinal cross-sectional view illustrating a cross-sectional structure when the positional relationship illustrated in FIG. 6A is viewed in a cross-sectional view taken along line B-B in FIG. 5C.

FIG. 7A is a plan view illustrating a positional relationship between the pad electrode and the sensing electrode included in the photodetection device according to the first embodiment of the present technology.

FIG. 7B is a longitudinal cross-sectional view illustrating a cross-sectional structure when the positional relationship illustrated in FIG. 7A is viewed in a cross-sectional view taken along line B-B in FIG. 5C.

FIG. 8A is a plan view illustrating a positional relationship between the pad electrode and the sensing electrode included in the photodetection device according to the first embodiment of the present technology.

FIG. 8B is a longitudinal cross-sectional view illustrating a cross-sectional structure when the positional relationship illustrated in FIG. 8A is viewed in a cross-sectional view taken along line B-B in FIG. 5C.

FIG. 9A is a schematic step cross-sectional view illustrating a manufacturing method for a semiconductor device according to the first embodiment of the present technology.

FIG. 9B is a schematic step cross-sectional view subsequent to FIG. 9A.

FIG. 9C is a schematic step cross-sectional view subsequent to FIG. 9B.

FIG. 9D is a schematic step cross-sectional view subsequent to FIG. 9C.

FIG. 9E is a schematic step cross-sectional view subsequent to FIG. 9D.

FIG. 10 is a longitudinal cross-sectional view illustrating an example in a case where bonding is performed by a wafer-on-wafer method.

FIG. 11A is a plan view illustrating a positional relationship between a pad electrode and a sensing electrode included in a photodetection device according to Modification 1 of the first embodiment of the present technology.

FIG. 11B is a longitudinal cross-sectional view illustrating a cross-sectional structure when the positional relationship illustrated in FIG. 11A is viewed in a cross-sectional view taken along line B-B in FIG. 5C.

FIG. 12A is a plan view illustrating a positional relationship between a pad electrode and a sensing electrode included in a photodetection device according to Modification 2 of the first embodiment of the present technology.

FIG. 12B is a longitudinal cross-sectional view illustrating a cross-sectional structure when the positional relationship illustrated in FIG. 12A is viewed in a cross-sectional view taken along line B-B in FIG. 5C.

FIG. 13A is a plan view illustrating a positional relationship between the pad electrode and the sensing electrode included in the photodetection device according to Modification 2 of the first embodiment of the present technology.

FIG. 13B is a longitudinal cross-sectional view illustrating a cross-sectional structure when the positional relationship illustrated in FIG. 13A is viewed in a cross-sectional view taken along line B-B in FIG. 5C.

FIG. 14A is a plan view illustrating a positional relationship between a pad electrode and a sensing electrode included in a photodetection device according to Modification 3 of the first embodiment of the present technology.

FIG. 14B is a longitudinal cross-sectional view illustrating a cross-sectional structure when the positional relationship illustrated in FIG. 14A is viewed in a cross-sectional view taken along line B-B in FIG. 5C.

FIG. 15 is a plan view illustrating a positional relationship between a pad electrode and a sensing electrode included in a photodetection device according to Modification 4 of the first embodiment of the present technology.

FIG. 16 is a plan view illustrating a positional relationship between a pad electrode and a sensing electrode included in a photodetection device according to Modification 5 of the first embodiment of the present technology.

FIG. 17 is a plan view illustrating a positional relationship between a pad electrode and a sensing electrode included in a photodetection device according to Modification 6 of the first embodiment of the present technology.

FIG. 18 is a plan view illustrating a positional relationship between a pad electrode and a sensing electrode included in a photodetection device according to Modification 7 of the first embodiment of the present technology.

FIG. 19 is a plan view illustrating a positional relationship between a pad electrode and a sensing electrode included in a photodetection device according to Modification 8 of the first embodiment of the present technology.

FIG. 20A is a plan view illustrating a positional relationship between a pad electrode and a sensing electrode included in a photodetection device according to Modification 9 of the first embodiment of the present technology.

FIG. 20B is a plan view illustrating a positional relationship between the pad electrode and the sensing electrode included in the photodetection device according to Modification 9 of the first embodiment of the present technology.

FIG. 21 is a longitudinal cross-sectional view illustrating a cross-sectional structure when a positional relationship between a pad electrode and a sensing electrode included in a photodetection device according to Modification 10 of the first embodiment of the present technology is viewed in a cross-sectional view taken along line B-B in FIG. 5C.

FIG. 22 is a plan view illustrating an inspection electrode included in a photodetection device according to Modification 11 of the first embodiment of the present technology.

FIG. 23 is a plan view illustrating an inspection electrode included in a photodetection device according to Modification 12 of the first embodiment of the present technology.

FIG. 24 is a block diagram illustrating an example of a schematic configuration of an electronic apparatus.

FIG. 25 is a block diagram illustrating an example of a schematic configuration of a vehicle control system.

FIG. 26 is an explanatory diagram illustrating an example of installation positions of an outside-vehicle information detector and an imaging section.

### MODE FOR CARRYING OUT THE INVENTION

Hereinafter, preferred modes for carrying out the present technology will be described with reference to the drawings. Note that, embodiments hereinafter described each illustrate an example of a representative embodiment of the present technology, and the scope of the present technology is not narrowed by them.

In the following drawings, the same or similar parts are denoted by the same or similar reference signs. It should be noted that the drawings are schematic, and a relationship between a thickness and a planar dimension, a ratio of the thicknesses between the respective layers, and the like are different from actual ones. Therefore, specific thicknesses and dimensions should be determined in consideration of the following description. Furthermore, it is needless to say that the drawings include portions having different dimensional relationships and ratios.

Furthermore, the embodiments described below each relate to an example of a device or a method for embodying the technical idea of the present technology, and the technical idea of the present technology does not limit the materials, shapes, structures, layouts, and the like of the components to those described below. Various changes can be made to the technical idea of the present technology within the technical scope defined by the claims disclosed in the claims.

The description is given in the following order.
1. First Embodiment
2. Example Application
Example Application to an Electronic Apparatus
Example Application to Mobile Object

### First Embodiment

In this embodiment, an example in which the present technology is applied to a photodetection device that is a back-illuminated complementary metal oxide semiconductor (CMOS) image sensor is described.

### Overall Configuration of Photodetection Device

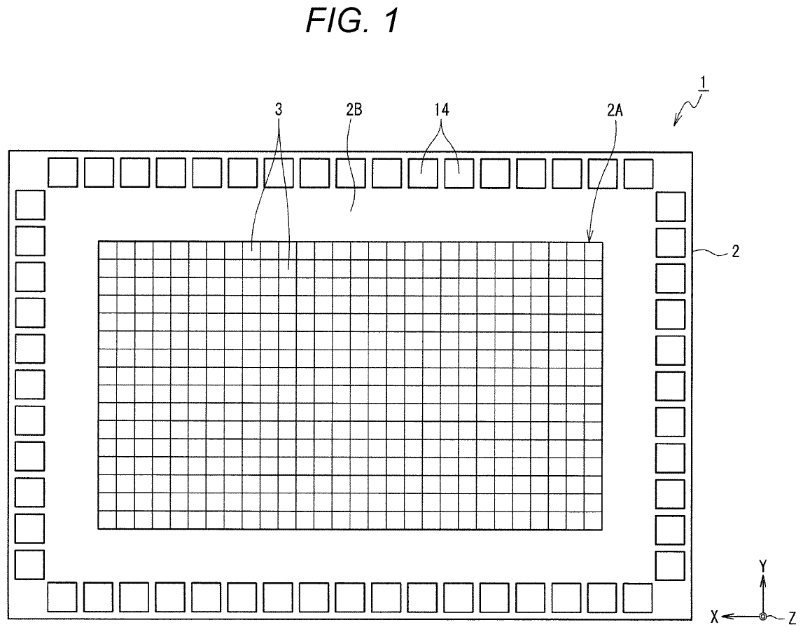

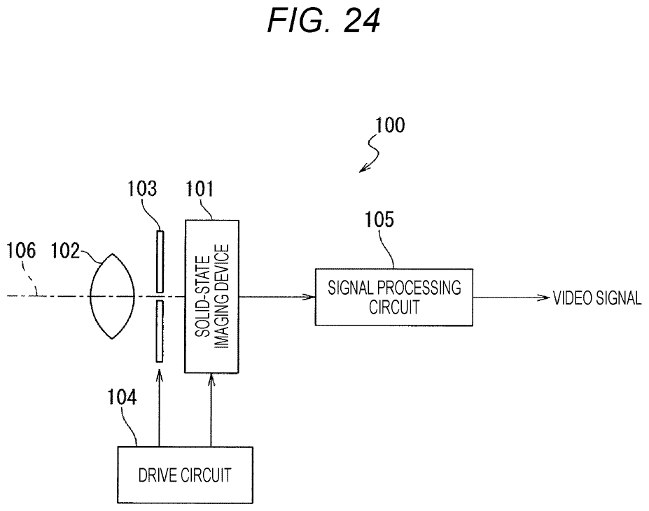

First, an overall configuration of a photodetection device 1 is described. The photodetection device 1 is an example of a semiconductor device. As illustrated in FIG. 1, the photodetection device 1 according to the first embodiment of the present technology is formed mainly with a semiconductor chip 2 having a rectangular two-dimensional planar shape in planar view. That is, the photodetection device 1 is mounted on the semiconductor chip 2. As illustrated in FIG. 24, the photodetection device 1 captures image light (incident light 106) from the subject via an optical system (optical lens) 102, converts the amount of the incident light 106 formed as an image on the imaging surface into an electrical signal pixel by pixel, and outputs the electrical signal as a pixel signal.

As illustrated in FIG. 1, the semiconductor chip 2 on which the photodetection device 1 is installed includes, in a two-dimensional plane including an X direction and a Y direction intersecting each other, a rectangular pixel region 2A provided in a central portion, and a peripheral region 2B provided outside the pixel region 2A to surround the pixel region 2A.

The pixel region 2A is a light receiving surface that receives light condensed by the optical system 102 illustrated in FIG. 24, for example. Then, in the pixel region 2A, a plurality of pixels 3 is arranged in a matrix in the two-dimensional plane including the X direction and the Y direction. In other words, the pixels 3 are repeatedly disposed in each of the X direction and the Y direction intersecting each other in the two-dimensional plane. Note that, in the present embodiment, the X direction and the Y direction are orthogonal to each other, for example. Furthermore, a direction orthogonal to both the X direction and the Y direction is a Z direction (thickness direction, stacking direction). Furthermore, a direction perpendicular to the Z direction is a horizontal direction.

As illustrated in FIG. 1, a plurality of bonding pads 14 is disposed in the peripheral region 2B. Each bonding pad of the plurality of bonding pads 14 is disposed along each of the four sides of the two-dimensional plane of the semiconductor chip 2, for example. Each bonding pad of the plurality of bonding pads 14 is an input-output terminal that is used when the semiconductor chip 2 is electrically connected to an external device.

### <Logic Circuit>

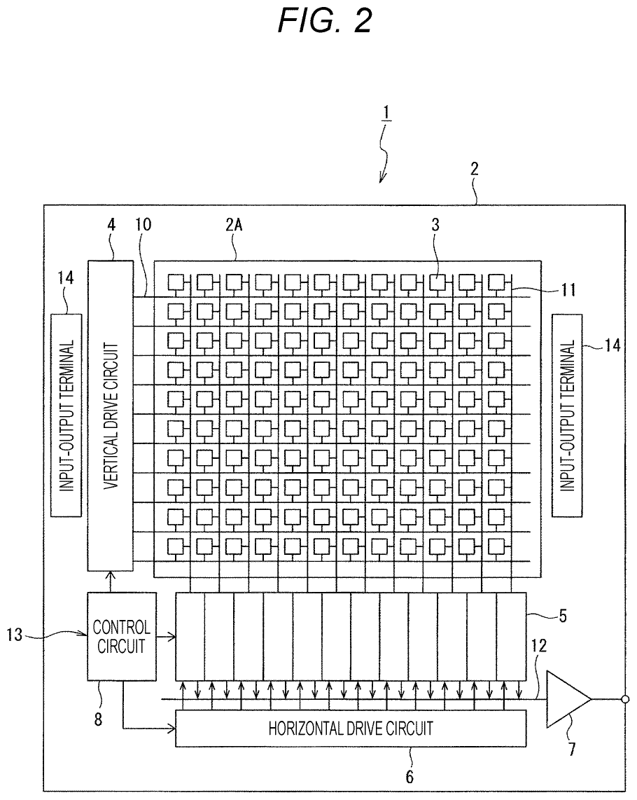

As illustrated in FIG. 2, the semiconductor chip 2 includes a logic circuit 13 including a vertical drive circuit 4, column signal processing circuits 5, a horizontal drive circuit 6, an output circuit 7, a control circuit 8, and the like. The logic circuit 13 includes a complementary MOS (CMOS) circuit including an n-channel conductive metal oxide semiconductor field effect transistor (MOSFET) and a p-channel conductive MOSFET as field effect transistors, for example.

The vertical drive circuit 4 includes a shift register, for example. The vertical drive circuit 4 sequentially selects a desired pixel drive line 10, supplies a pulse for driving the pixels 3 to the selected pixel drive line 10, and drives the respective pixels 3 row by row. That is, the vertical drive circuit 4 selectively scans each of the pixels 3 in the pixel region 2A sequentially in a vertical direction on a row-by-row basis, and supplies a pixel signal from each of the pixels 3 based on a signal charge generated in accordance with the amount of received light by a photoelectric conversion element of the pixel 3 to the column signal processing circuit 5 through a vertical signal line 11.

The column signal processing circuits 5 are disposed on the respective columns of the pixels 3, for example, and perform, for the respective pixel columns, signal processing such as noise removal on signals to be output from the pixels 3 of one row. For example, each column signal processing circuit 5 performs signal processing such as correlated double sampling (CDS) for removing pixel-specific fixed pattern noise, and analog-to-digital (AD) conversion. A horizontal selection switch (not shown) is disposed in the output stage of each column signal processing circuit 5, and is connected to a horizontal signal line 12.

The horizontal drive circuit 6 includes a shift register, for example. The horizontal drive circuit 6 sequentially outputs horizontal scanning pulses to the column signal processing circuits 5 to sequentially select each of the column signal processing circuits 5, and causes each of the column signal processing circuits 5 to output a pixel signal subjected to signal processing to the horizontal signal line 12.

The output circuit 7 performs signal processing on pixel signals sequentially supplied from the individual column signal processing circuits 5 through the horizontal signal line 12, and outputs a processed signal. As the signal processing, buffering, black level adjustment, column variation correction, various kinds of digital signal processing, and the like can be used, for example.

The control circuit 8 generates a clock signal and a control signal that are references for operations of the vertical drive circuit 4, the column signal processing circuits 5, the horizontal drive circuit 6, and the like, on the basis of a vertical synchronization signal, a horizontal synchronization signal, and a master clock signal. Then, the control circuit 8 outputs the generated clock signal and control signal to the vertical drive circuit 4, the column signal processing circuits 5, the horizontal drive circuit 6, and the like.

### <Pixel>

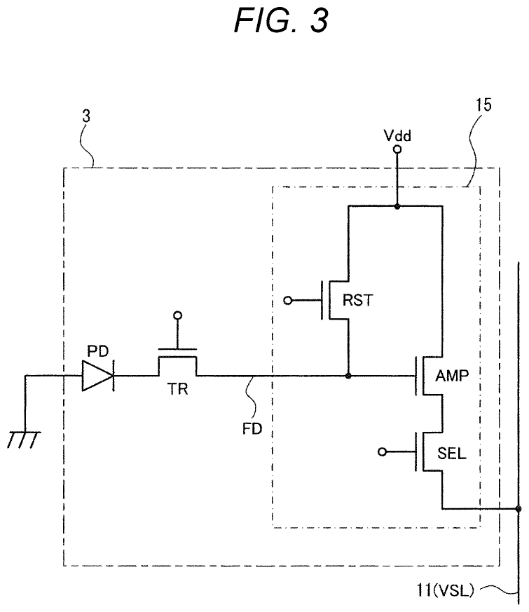

FIG. 3 is an equivalent circuit diagram illustrating a configuration example of the pixel 3. The pixel 3 includes a photoelectric conversion element PD, a charge accumulation region (floating diffusion) FD that accumulates (holds) a signal charge photoelectrically converted by the photoelectric conversion element PD, and a transfer transistor TR that transfers the signal charge photoelectrically converted by the photoelectric conversion element PD to the charge accumulation region FD. Furthermore, the pixel 3 includes a readout circuit 15 electrically connected to the charge accumulation region FD.

The photoelectric conversion element PD generates a signal charge corresponding to the amount of received light. Furthermore, the photoelectric conversion element PD temporarily accumulates (holds) the generated signal charge. The photoelectric conversion element PD has a cathode side electrically connected to a source region of the transfer transistor TR, and an anode side electrically connected to a reference potential line (for example, ground). As the photoelectric conversion element PD, for example, a photodiode is used.

The drain region of each transfer transistor TR is electrically connected to the charge accumulation region FD. A gate electrode of each transfer transistor TR is electrically connected to a transfer transistor drive line among the pixel drive lines 10 (see FIG. 2).

The charge accumulation region FD temporarily accumulates and holds the signal charge transferred from the photoelectric conversion element PD via the transfer transistor TR.

The readout circuit 15 reads the signal charge accumulated in the charge accumulation region FD, and outputs a pixel signal based on the signal charge. Although not limited to this, the readout circuit 15 includes an amplification transistor AMP, a selection transistor SEL, and a reset transistor RST as pixel transistors, for example. Each of these transistors (AMP, SEL, and RST) includes a MOSFET including a gate insulating film formed with a silicon oxide film (SiO₂ film), a gate electrode, and a pair of main electrode regions functioning as the source region and the drain region, for example. Furthermore, these transistors may be a metal insulator semiconductor FET (MISFET) whose gate insulating film is a silicon nitride film (Si₃N₄ film) or a laminated film of a silicon nitride film and a silicon oxide film.

The amplification transistor AMP has a source region electrically connected to a drain region of the selection transistor SEL, and a drain region electrically connected to a power supply line Vdd and a drain region of the reset transistor. Then, a gate electrode of the amplification transistor AMP is electrically connected to the charge accumulation region FD and a source region of the reset transistor RST.

The selection transistor SEL has a source region electrically connected to the vertical signal line 11 (VSL), and a drain electrically connected to the source region of the amplification transistor AMP. Then, a gate electrode of the selection transistor SEL is electrically connected to a selection transistor drive line among the pixel drive lines 10 (see FIG. 2).

The reset transistor RST has a source region electrically connected to the charge accumulation region FD and the gate electrode of the amplification transistor AMP, and a drain region electrically connected to the power supply line Vdd and the drain region of the amplification transistor AMP. A gate electrode of the reset transistor RST is electrically connected to a reset transistor drive line among the pixel drive lines 10 (see FIG. 2).

### <<Specific Configuration of Photodetection Device>>

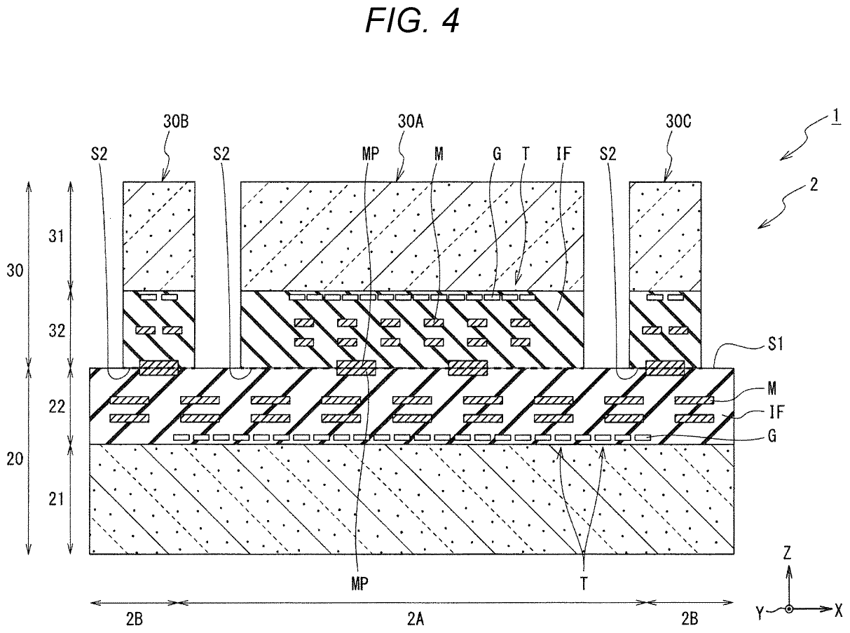

Next, a specific configuration of a photodetection device 1 will be described with reference to FIGS. 4 to 8B.

### <Configuration of Semiconductor Chip>

As illustrated in FIG. 4, the semiconductor chip 2 mounted with the photodetection device 1 includes a first semiconductor chip 20 and a second semiconductor chip 30 that is bonded to the first semiconductor chip 20. That is, the semiconductor chip 2 includes multiple semiconductor chips that are bonded. First, the second semiconductor chip 30 will be described.

A size of the second semiconductor chip 30 in plan view is smaller than that of the first semiconductor chip 20. Then, the second semiconductor chip 30 is bonded to a first joint surface S1 of the first semiconductor chip 20. The second semiconductor chip 30 includes a semiconductor layer 31 and a wiring layer 32 stacked on one surface of the semiconductor layer 31. Although not limited thereto, the semiconductor layer 31 is, for example, a semiconductor substrate of silicon the like, in which an active element such as a transistor T is formed. The wiring layer 32 is a multilayer wiring layer having a multilayer structure in which an insulating film IF and a metal wiring line M are alternately laminated in multiple stages. Then, a surface of the wiring layer 32 opposite to the semiconductor layer 31 side is a second joint surface S2, and the second joint surface S2 is bonded to the first joint surface S1 of the first semiconductor chip 20. Furthermore, the wiring layer 32 is provided with a gate electrode G of the transistor T and a metal connection pad MP facing the second joint surface S2.

In the second semiconductor chip 30, any of the logic circuit 13 described above, the readout circuit 15 described above, a storage circuit such as a memory, and a circuit constituting artificial intelligence (AI) is mounted.

Furthermore, in the example illustrated in FIG. 4, three second semiconductor chips 30 are bonded to the first semiconductor chip 20. These three second semiconductor chips 30 are referred to as a second semiconductor chip 30A, a second semiconductor chip 30B, and a second semiconductor chip 30C in order to distinguish the three second semiconductor chips 30. Note that, the second semiconductor chips 30A, 30B, and 30C are simply referred to as the second semiconductor chip 30 in a case of not being distinguished from each other. Furthermore, the number of the second semiconductor chips 30 bonded to the first semiconductor chip 20 is not limited to the example illustrated in FIG. 4, and may be two or less or four or more. In each of the second semiconductor chips 30A, 30B, and 30C, any of the logic circuit 13, the readout circuit 15, a storage circuit such as a memory, and a circuit constituting artificial intelligence (AI) is mounted. Note that, the same type of circuits may be mounted in all of the second semiconductor chips 30A, 30B, and 30C, or individually with different circuits may be mounted. Furthermore, the same type of circuits may be mounted in multiple chips (for example, the second semiconductor chips 30A and 30B) out of the second semiconductor chips 30A, 30B, and 30C, and while a different circuit may be mounted in a remaining chip (for example, the second semiconductor chip 30C).

The first semiconductor chip 20 includes a semiconductor layer 21 and a wiring layer 22 stacked on one surface of the semiconductor layer 21. Although not limited thereto, the semiconductor layer 21 is, for example, a semiconductor substrate of silicon the like, in which an active element such as the transistor T is formed. In the semiconductor layer 21, the pixel region 2A and the photoelectric conversion element PD described above are formed. Furthermore, for example, a color filter, a microlens, and the like (not illustrated) may be further provided on another surface side (light receiving surface side) of the semiconductor layer 21. The color filter and the microlens each are provided for every pixel 3, and are made containing, for example, a resin material.

The wiring layer 22 is a multilayer wiring layer having a multilayer structure in which the insulating film IF and the metal wiring line M are alternately laminated in multiple stages. Then, a surface of the wiring layer 22 opposite to the semiconductor layer 21 side is the first joint surface S1. Furthermore, the wiring layer 22 is provided with the gate electrode G of the transistor T and the metal connection pad MP facing the first joint surface S1. The connection pad MP of the first semiconductor chip 20 is connected to the connection pad MP of the second semiconductor chip 30. With this configuration, the circuit mounted on the first semiconductor chip 20 and the circuit mounted on the second semiconductor chip 30 are electrically connected.

A size of the first joint surface S1 is larger than a size of the second joint surface S2 of one second semiconductor chip 30, and is further larger than a size obtained by adding the second joint surfaces S2 of all the second semiconductor chips 30 bonded to the first joint surface S1. The second semiconductor chip 30A is bonded to a region overlapping with the pixel region 2A of the first semiconductor chip 20 in plan view. Then, in a portion of the first semiconductor chip 20 corresponding to the pixel region 2A, many transistors T and wiring lines M are provided due to miniaturization and high density of the pixel 3.

A material contained in the insulating film IF of the first semiconductor chip 20 and the second semiconductor chip 30 and a metal contained in the wiring line M and the connection pad MP are known materials. Examples of the material contained in the insulating film IF include, but not limited to, silicon oxide (SiO₂). Examples of the material contained in the wiring line M and the connection pad MP include, but not limited to, copper (Cu), aluminum (Al), titanium (Ti), and tantalum (Ta). The wiring line M and the connection pads MP are formed using a known technique such as damascene, for example, although not limited thereto.

### <Wafer and Chip Region>

The second semiconductor chip 30 is formed in a wafer different from the first semiconductor chip 20, and is then singulated. The singulated second semiconductor chip 30 is bonded to the first semiconductor chip 20 before being singulated. That is, the semiconductor chip 2 mounted with the photodetection device 1 is formed by CoW (chip-on-wafer).

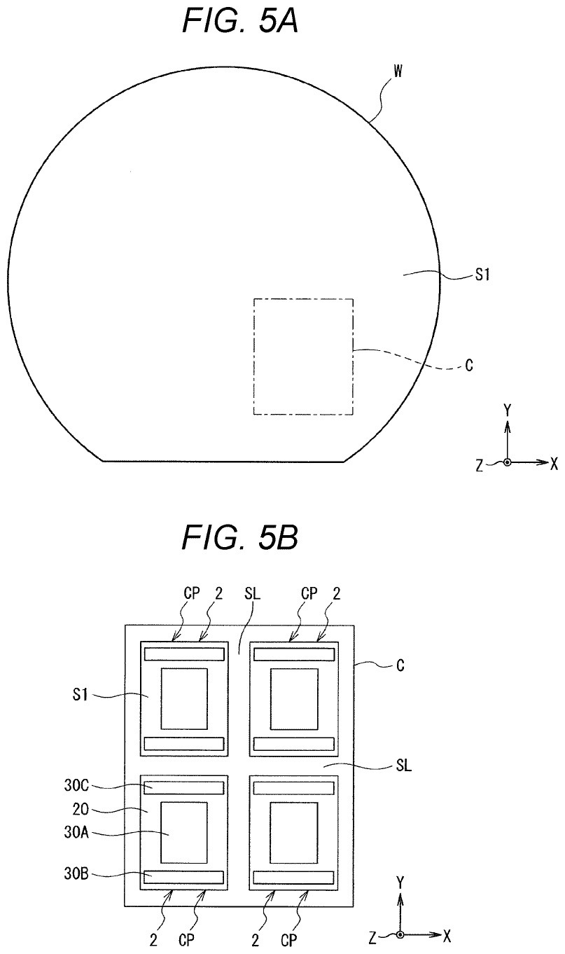

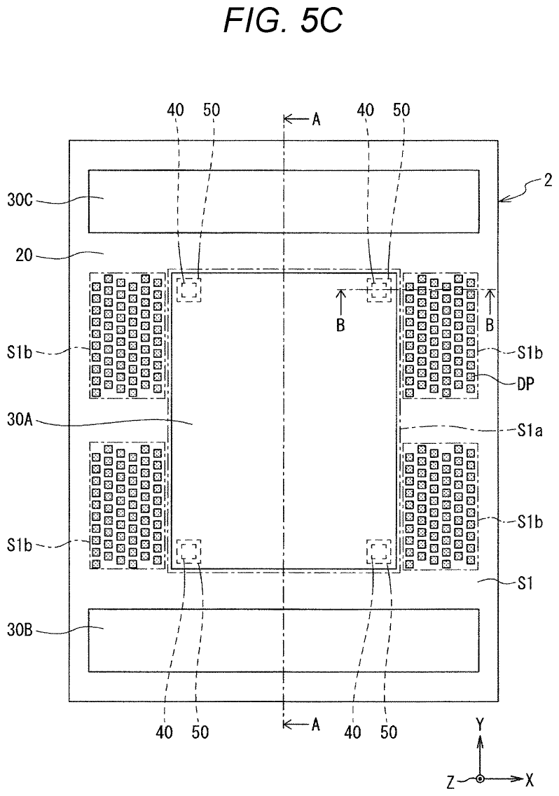

FIGS. 5A to 5C illustrate a state before singulation of the semiconductor chip 2 mounted with the photodetection device 1. FIG. 5A is a plan view of a semiconductor wafer W in which one surface is the first joint surface S1. FIG. 5B is an enlarged plan view illustrating a C region of the semiconductor wafer W illustrated in FIG. 5A. FIG. 5C is an enlarged plan view illustrating one of the multiple semiconductor chips 2 (chip regions CP) illustrated in FIG. 5B. Furthermore, a cross-sectional structure when viewed in a cross-sectional view taken along line A-A of FIG. 5C is the cross-sectional structure illustrated in FIG. 4.

As illustrated in FIG. 5B, the semiconductor wafer W includes multiple chip regions CP which are regions to be divided into the first semiconductor chips 20. Then, the singulated second semiconductor chip 30 is bonded to each of the chip regions CP (first semiconductor chips 20), to form the semiconductor chip 2 in a state before being singulated mounted with the photodetection device 1. The chip regions CP are partitioned by a scribe line (dicing region) SL, and are repeatedly disposed in each of the X direction and the Y direction via the scribe line SL. That is, the multiple chip regions CP are arranged in a matrix on the semiconductor wafer W. Then, the multiple chip regions CP are individually singulated along the scribe line SL to form the first semiconductor chip 20 (semiconductor chip 2). Note that the scribe line SL is not physically formed.

### <First Joint Surface>

As illustrated in FIG. 5C, three second semiconductor chips, that is, the second semiconductor chips 30A, 30B, and 30C are joined to the first joint surface S1. These second semiconductor chips 30 each are similarly bonded to the first joint surface S1. Therefore, the bonding of CoW will be described using the second semiconductor chip 30A as an example.

The first joint surface S1 includes a first region S1a and a second region S1b that is a region other than the first region S1a. The first region S1a is a region prepared for bonding the second semiconductor chip 30A, and the second semiconductor chip 30A is bonded as illustrated in FIG. 5C. At four corners of the second semiconductor chip 30A, pad electrodes 40 facing the second joint surface S2 are provided. Then, sensing electrodes 50 facing the first joint surface S1 are provided at four corners of the first region S1a. The sensing electrode 50 is provided at a position corresponding to the pad electrode 40. More specifically, the sensing electrode 50 is provided at a position overlapping with the pad electrode 40 in plan view, when the second semiconductor chip 30A is bonded to the first semiconductor chip 20. A size of the sensing electrode 50 is, but not limited to, for example, within a range of 50 μm² or less in plan view. Furthermore, for example, the sensing electrode 50 has a size that falls within a range of 10 μm² to 20 μm² or less in plan view.

The second region S1b is a margin region to which no second semiconductor chip is bonded, and a plurality of dummy pads DP is provided as illustrated in FIG. 5C. The dummy pad DP faces the second region S1b, is made containing the same material as the material contained in the connection pad MP of the first semiconductor chip 20, and is a member not contributing to the circuit configuration, for example, an electrically floating member. The reason why the dummy pads DP are provided in the margin region such as the second region S1b will be described below. In a step of forming the connection pad MP of the first semiconductor chip 20, dry etching or chemical mechanical polishing (CMP) may be performed on the entire surface of the semiconductor wafer W. Then, in order to suppress a change in uniformity in the plane of the semiconductor wafer W in such a dry etching or chemical mechanical polishing (CMP) step, the dummy pad DP is also provided in a region where no pattern is originally provided. In the present embodiment, some dummy pads DP among the multiple dummy pads DP are used as an inspection electrodes 60 described later.

### <Pad Electrode and Sensing Electrode>

Since the pad electrode 40 is formed together with the connection pad MP of the second semiconductor chip 30A, the pad electrode 40 is made containing the same material as the material contained in the connection pad MP. Since the sensing electrode and the dummy pad DP are formed together with the connection pad MP of the first semiconductor chip 20, the sensing electrode 50 and the dummy pad DP are made containing the same material as the material contained in the connection pad MP. Note that the material contained in the connection pad MP is as described above. In the present embodiment, the description will be given on assumption that the material contained in the pad electrode 40, the sensing electrode 50, the dummy pad DP, and the connection pad MP is copper.

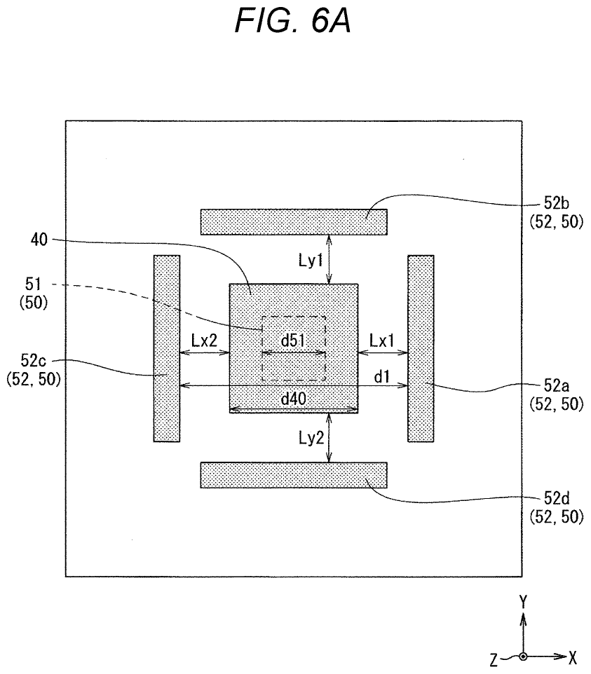

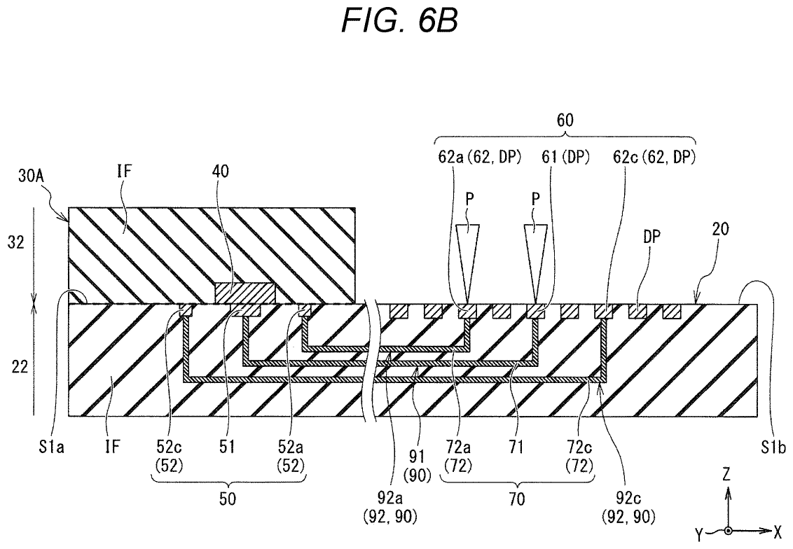

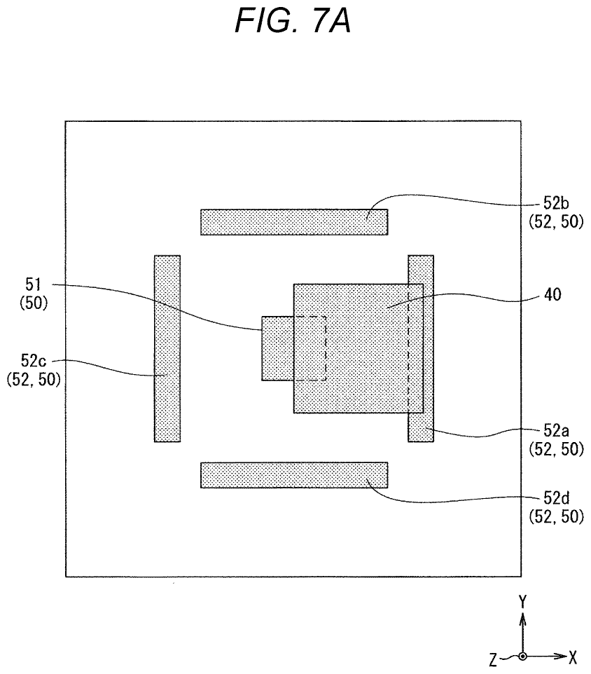

FIGS. 6A and 6B illustrate a positional relationship between the pad electrode 40 and the sensing electrode 50 in a state where the second semiconductor chip 30A is bonded to the first semiconductor chip 20 with ideal alignment designed. In such a state, a center of the pad electrode 40 and a center of a first sensing electrode 51 described later are designed to overlap with each other in plan view. As illustrated in FIG. 6A, in plan view, the pad electrode 40 is a polygonal electrode, and the first sensing electrode 51 is a polygonal electrode having the same number of sides as the pad electrode 40. The pad electrode 40 is a rectangular electrode, in the present embodiment, a square electrode having a side dimension of d40 in plan view. That is, a width of the pad electrode 40 is d40. The sensing electrode 50 includes the first sensing electrode 51 facing the first region S1a and a second sensing electrode 52 facing the first region S1a and surrounding the first sensing electrode 51. The first sensing electrode 51 is a rectangular electrode, in the present embodiment, a square electrode having a side dimension of d51 in plan view. That is, a width of the first sensing electrode 51 is d51. In plan view, the first sensing electrode 51 is smaller than the pad electrode 40. That is, the dimension d51 of one side of the first sensing electrode 51 is smaller than the dimension d40 of one side of the pad electrode 40 (d51<d40). Furthermore, the first sensing electrode 51 is electrically separated from the second sensing electrode 52.

The second sensing electrode 52 includes a plurality of second sensing electrode portions electrically separated from each other and arranged along a line surrounding the first sensing electrode 51. More specifically, the second sensing electrode 52 includes four second sensing electrode portions 52a, 52b, 52c, and 52d. Note that, the plurality of (four in the present embodiment) second sensing electrode portions 52a, 52b, 52c, and 52d may be collectively referred to as the second sensing electrode 52. Furthermore, the second sensing electrode portions 52a, 52b, 52c, and 52d each may be referred to as a second sensing electrode portion 52 in a case of not being distinguished from each other.

The second sensing electrode portion 52 is, for example, a rectangular electrode. The second sensing electrode portion 52 is an oblong electrode in the present embodiment. The second sensing electrode portions 52 are provided in equal number to the number of sides of the pad electrode 40 (four in the present embodiment). More specifically, the second sensing electrode portions 52 are provided in equal number to the number of sides of the pad electrode 40 and the first sensing electrode 51. The second sensing electrode portion 52 is disposed around the first sensing electrode 51 in four directions (+X direction, −x direction, +Y direction, and −Y direction) of the first sensing electrode 51. More specifically, the second sensing electrode portions 52a and 52c are disposed with the first sensing electrode 51 interposed in between along the X direction. Then, the second sensing electrode portions 52a and 52c are disposed such that long sides thereof are opposed to each other, and the opposed long sides are parallel to each other. Then, the second sensing electrode portions 52b and 52d are disposed with the first sensing electrode 51 interposed in between along the Y direction orthogonal to the X direction. Then, the second sensing electrode portions 52b and 52d are disposed such that long sides thereof are opposed to each other, and the opposed long sides are parallel to each other.

A distance between the second sensing electrode portion 52a and the second sensing electrode portion 52c opposed to each other with the first sensing electrode 51 interposed in between is the same as a distance between the second sensing electrode portion 52b and the second sensing electrode portion 52d. Here, the distance is referred to as a distance d1. Then, the width d40 of the pad electrode 40 is smaller than distance d1 and larger than the distance between the first sensing electrode 51 and the second sensing electrode portion 52. The distance d1 can be defined as d1=d40+Lx1+Lx2 using distances Lx1 and Lx2 described later. Furthermore, the distance d1 can be defined as d1=d40+Ly1+Ly2 using distances Ly1 and Ly2 described later.

Furthermore, in the present embodiment, since the first sensing electrode 51 is a polygonal electrode having the same number of sides as the pad electrode 40, the second sensing electrode portion 52 is disposed such that a long side thereof is opposed to each side of the first sensing electrode 51. Then, the second sensing electrode portion 52 is disposed such that a long side opposed to the first sensing electrode 51 is parallel to a side of the first sensing electrode 51. Furthermore, the second sensing electrode portions 52 are separated from each other at diagonal positions of the first sensing electrode 51. Each of the second sensing electrode portions 52a, 52b, 52c, and 52d is provided at a position equidistant from the first sensing electrode 51.

As illustrated in FIG. 6A, in a state where the second semiconductor chip 30A is bonded to the first semiconductor chip 20 with ideal alignment designed, the second sensing electrode portion 52 is disposed such that a long side thereof is opposed to each side of the pad electrode 40. Then, the second sensing electrode portion 52 is disposed such that a long side opposed to the pad electrode 40 is parallel to a side of the pad electrode 40. Furthermore, in the ideal state described above, the distance Lx1 between the pad electrode 40 and the second sensing electrode portion 52a is equal to the distance Lx2 between the pad electrode 40 and the second sensing electrode portion 52c (Lx1=Lx2). Similarly, the distance Ly1 between the pad electrode 40 and the second sensing electrode portion 52b is equal to the distance Ly2 between the pad electrode 40 and the second sensing electrode portion 52d (Ly1=Ly2). Moreover, in the present embodiment, all of the distance Lx1, the distance Lx2, the distance Ly1, and the distance Ly2 have the same value (Lx1=Lx2=Ly1=Ly2). Then, the distances Lx1, Lx2, Ly1, and Ly2 are management values of misalignment between the second semiconductor chip 30A and the first semiconductor chip 20, and may be referred to as management values Lx1, Lx2, Ly1, and Ly2. More specifically, Lx1 and Lx2 are management values of misalignment in the X direction, and Ly1 and Ly2 are management values of misalignment in the Y direction. The management value is not limited thereto, but may be, for example, on a submicron order. Furthermore, the management value may be on a micron order, for example, may be 1 μm or more and 3 μm or less. It suffices that the management value is set in accordance with a margin of bonding misalignment between the second semiconductor chip 30A and the first semiconductor chip 20.

### <Inspection Electrode and Connection Wiring Line>

As illustrated in FIG. 6B, the first semiconductor chip 20 includes the inspection electrode 60 facing the second region S1b and including the dummy pad DP, and a connection wiring line 70 that is provided in the wiring layer 22 and electrically connects the sensing electrode 50 to the inspection electrode 60.

The inspection electrode 60 includes a first inspection electrode 61 and a second inspection electrode 62. Note that, the first inspection electrode 61 and the second inspection electrode 62 are simply referred to as the inspection electrode 60 in a case of not being distinguished from each other. The first inspection electrode 61 is electrically separated from the second inspection electrode 62. Furthermore, a plurality of second inspection electrodes 62 is provided. More specifically, the second inspection electrodes 62 are provided in equal number to the number of the second sensing electrode portions 52 (four in the present embodiment). The second inspection electrodes 62 are electrically separated from each other. FIG. 6B illustrates only a second inspection electrode 62a and a second inspection electrode 62c among the plurality of second inspection electrodes 62. The plurality of second inspection electrodes 62 such as the second inspection electrode 62a and the second inspection electrode 62c is simply referred to as the second inspection electrode 62 in a case of not being distinguished from each other.

The connection wiring line 70 includes a first connection wiring line 71 that electrically connects the first sensing electrode 51 to the first inspection electrode 61, and a second connection wiring line 72 that electrically connects the second sensing electrode 52 to the second inspection electrode 62. The first connection wiring line 71 and the second connection wiring line 72 are simply referred to as the connection wiring line 70 in a case of not being distinguished from each other. The first connection wiring line 71 is electrically separated from the second connection wiring line 72. Furthermore, a plurality of the second connection wiring lines 72 is provided. More specifically, the second connection wiring lines 72 are provided in equal number to the number of the second sensing electrode portions 52 (four in the present embodiment). The second connection wiring lines 72 are electrically separated from each other. Among the plurality of second connection wiring lines 72, FIG. 6B illustrates only a second connection wiring line 72a that electrically connects the second sensing electrode 52a to the second inspection electrode 62a and a second connection wiring line 72c that electrically connects the second sensing electrode 52c to the second inspection electrode 62c. The plurality of second connection wiring lines 72 such as the second connection wiring line 72a and the second connection wiring line 72c is simply referred to as the second connection wiring line 72 in a case of not being distinguished from each other.

The connection wiring line 70 is, but not limited to, for example, a metal wiring line including a metal wiring line provided via the insulating film IF, a via provided along a thickness direction of the insulating film IF, or the like. Examples of the material contained in the connection wiring line 70 include, but not limited to, copper (Cu), aluminum (Al), tungsten (W), and the like. The connection wiring line 70 can be made containing the same material as the wiring line M belonging to the same layer, and the same process as the wiring line M and the connection pad MP belonging to the same layer can also be used for a manufacturing process such as damascene.

### <Set>

As described above, the second inspection electrode 62 and the second connection wiring line 72 are provided for each of the second sensing electrode portions 52. That is, a plurality of sets 92 of the second sensing electrode portion 52, the second inspection electrode 62, and the second connection wiring line 72 is provided. Then, the sets 92 are electrically separated from each other. FIG. 6B illustrates a set 92a of the second sensing electrode portion 52a, the second inspection electrode 62a, and the second connection wiring line 72a, and a set 92c of the second sensing electrode portion 52c, the second inspection electrode 62c, and the second connection wiring line 72c. Note that, the plurality of sets such as the set 92a and the set 92c is simply referred to as the set 92 in a case of not being distinguished from each other.

Only one set 91 of the first sensing electrode 51, the first inspection electrode 61, and the first connection wiring line 71 is provided, and the set 91 and the set 92 are electrically separated from each other. Note that, the set 91 and the set 92 are simply referred to as a set 90 in a case of not being distinguished from each other.

### <Functions>

Whether or not misalignment of bonding between the second semiconductor chip 30A and the first semiconductor chip 20 is smaller than a management value can be determined by checking presence or absence of electrical conduction between the set 91 and the set 92 by using a pair of probes P. More specifically, whether or not misalignment is smaller than the management value can be determined by checking presence or absence of electrical conduction between a pair of two inspection electrodes among the plurality of inspection electrodes 60 by using the pair of probes P while changing the pair, since the first inspection electrode 61 and the plurality of second inspection electrodes 62 are exposed to the second region S1b. More specifically, whether or not misalignment is smaller than the management value can be determined by checking presence or absence of electrical conduction between a pair including the first inspection electrode 61 and one of the plurality of second inspection electrodes 62 by using the pair of probes P while changing the pair. Hereinafter, the determination will be described in detail.

First, with reference to FIGS. 6A and 6B, a case will be described in which the second semiconductor chip 30A is bonded to the first semiconductor chip 20 with misalignment smaller than the management value. For example, as illustrated in FIGS. 6A and 6B, it is assumed that the pad electrode 40 is connected only to the first sensing electrode 51, out of the first sensing electrode 51 and the second sensing electrode 52 included in the sensing electrode 50.

In this state, when the presence or absence of electrical conduction between the first inspection electrode 61 and one second inspection electrode 62 is checked by using the pair of probes P while changing the pair, electrical conduction is not detected in either pair. As a result, it can be seen that the set 91 and the set 92 are electrically separated. Then, as a result, it can be determined that the second semiconductor chip 30A is bonded to the first semiconductor chip 20 with misalignment smaller than the management value.

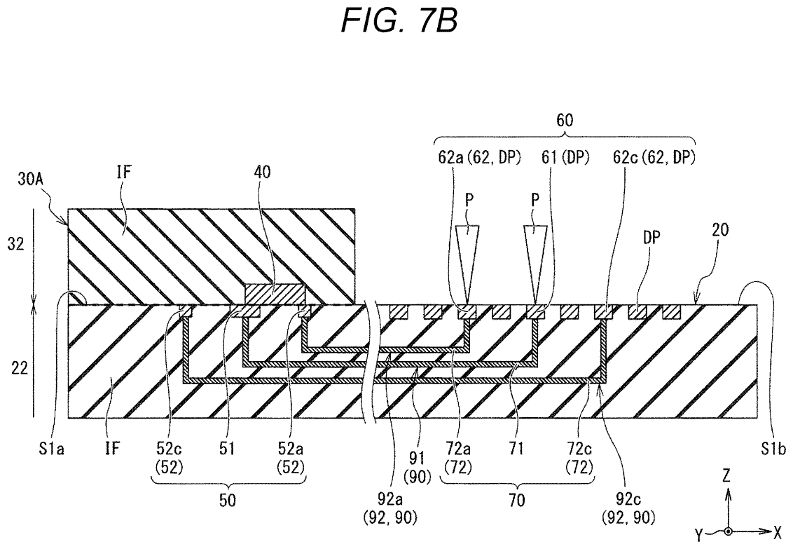

Next, with reference to FIGS. 7A and 7B, a case will be described in which the second semiconductor chip 30A is bonded to the first semiconductor chip 20 with misalignment equal to or larger than the management value. For example, as illustrated in FIGS. 7A and 7B, it is assumed that the second semiconductor chip 30A is deviated to the right side in the page and bonded to the first semiconductor chip 20. More specifically, it is assumed that the second semiconductor chip 30A is bonded to the first semiconductor chip 20 with misalignment equal to or larger than the management value Lx1 toward the right side of the page. The pad electrode 40 is relatively deviated to the right side in the page, and is connected to both the first sensing electrode 51 and the second sensing electrode portion 52a to short-circuit the two. It is assumed that the set 91 and the set 92a are short-circuited as a result.

In this state, when the presence or absence of electrical conduction between the first inspection electrode 61 and one second inspection electrode 62 is checked by using the pair of probes P while changing the pair, it is detected that only the pair of the first inspection electrode 61 and the second inspection electrode 62a illustrated in FIG. 7B has electrical conduction, that is, is short-circuited. As a result, it can be seen that only the set 91 and the set 92a are short-circuited. Then, as a result, it can be determined that the second semiconductor chip 30A is bonded to the first semiconductor chip 20 with misalignment equal to or larger than the management value Lx1 toward the right side (+X direction) in the page. In this manner, it is possible to detect whether or not the second semiconductor chip 30A is bonded to the first semiconductor chip 20 with misalignment equal to or larger than the management value. Furthermore, since the second sensing electrode 52 includes the four second sensing electrode portions 52a, 52b, 52c, and 52d, which direction the second semiconductor chip 30A is deviated in with respect to the first semiconductor chip 20 can be specified. More specifically, it is possible to specify which direction out of the right side (+X direction) in the page, the left side (−X direction) in the page, the upper side (+Y direction) in the page, and the lower side (−Y direction) in the page the second semiconductor chip 30A is deviated in with respect to the first semiconductor chip 20.

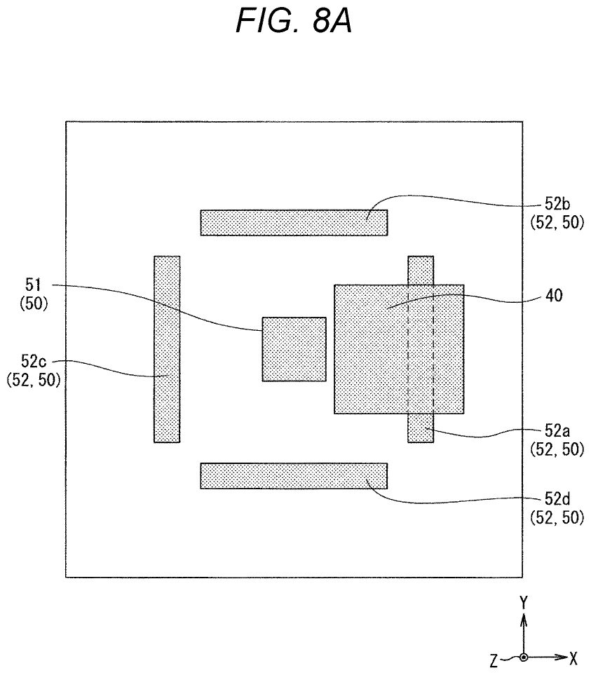

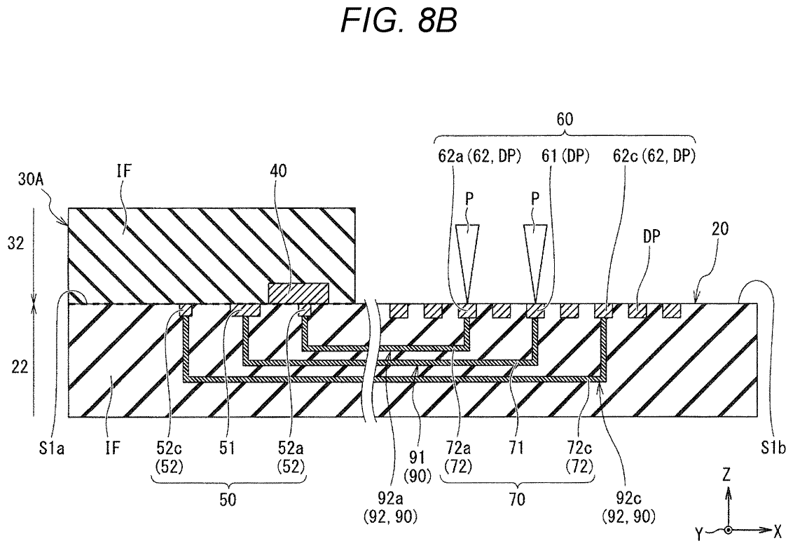

Next, with reference to FIGS. 8A and 8B, a case will be described in which the second semiconductor chip 30A is bonded to the first semiconductor chip 20 with misalignment exceeding a detectable range. As illustrated in FIGS. 8A and 8B, it is assumed that the second semiconductor chip 30A is bonded to the first semiconductor chip 20 with misalignment exceeding a detectable range to the right side of the page. More specifically, it is assumed that the pad electrode 40 is deviated to the right side in the page beyond the detectable range, and is connected only to the second sensing electrode 52 out of the first sensing electrode 51 and the second sensing electrode 52.

In this state, when the presence or absence of electrical conduction between the first inspection electrode 61 and one second inspection electrode 62 is checked by using the pair of probes P while changing the pair, electrical conduction is not detected in either pair. That is, even though the second semiconductor chip is bonded to the first semiconductor chip with misalignment greatly exceeding the management value, it is not possible to distinguish from the case where the second semiconductor chip 30A is bonded to the first semiconductor chip 20 with misalignment smaller than the management value. This is a case of bonding with misalignment exceeding the detectable range.

The detectable range can be defined as [−(d40+d51)/2] or more and [+(d40+d51)/2] or less. Note that, as illustrated in FIG. 6A, d40 is a width of the pad electrode 40, and d51 is a width of the first sensing electrode 51. When a misalignment amount exceeds the detectable range, it cannot be determined whether or not the second semiconductor chip 30A is bonded to the first semiconductor chip 20 with a misalignment amount smaller than the management value. Note that, in order to widen the detectable range, it is only necessary to increase d51, which is a width of the first sensing electrode 51.

### <<Manufacturing Method for Photodetection Device>>

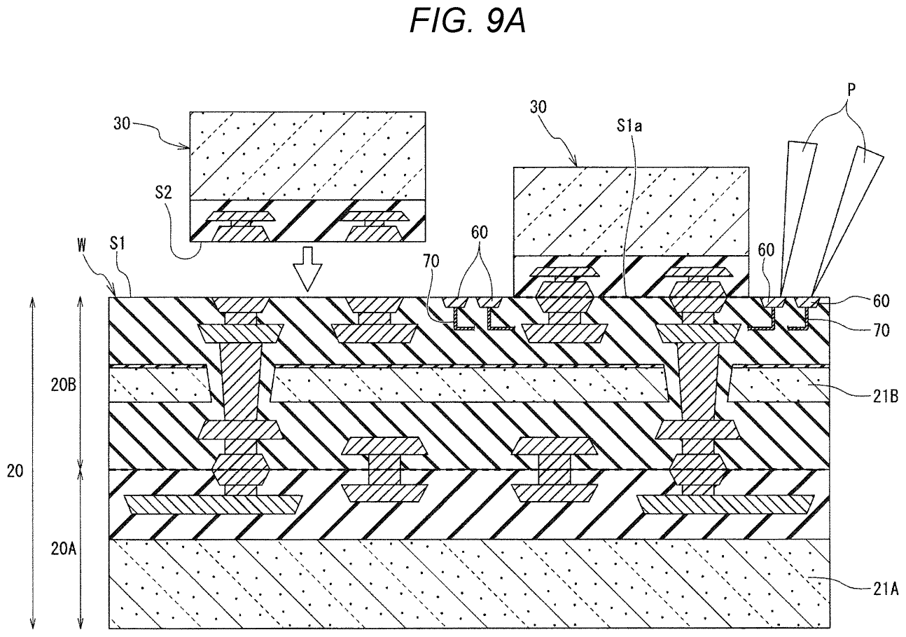

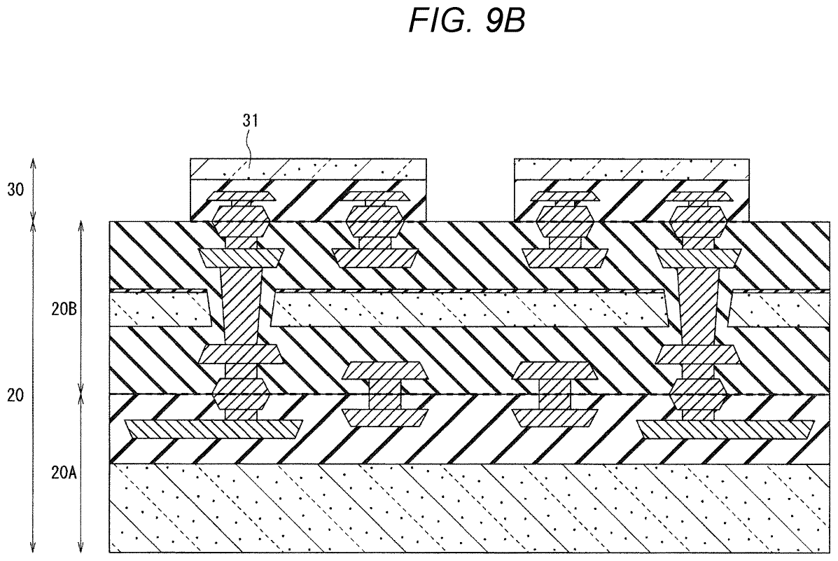

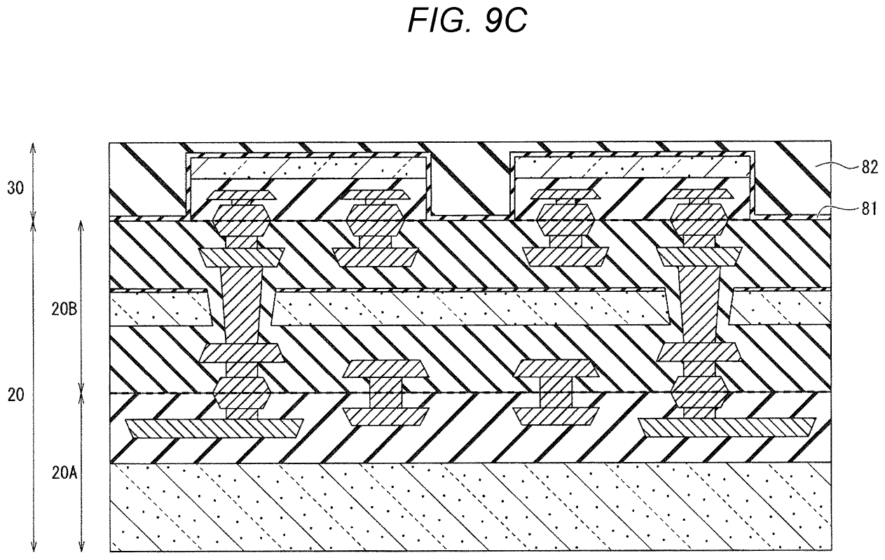

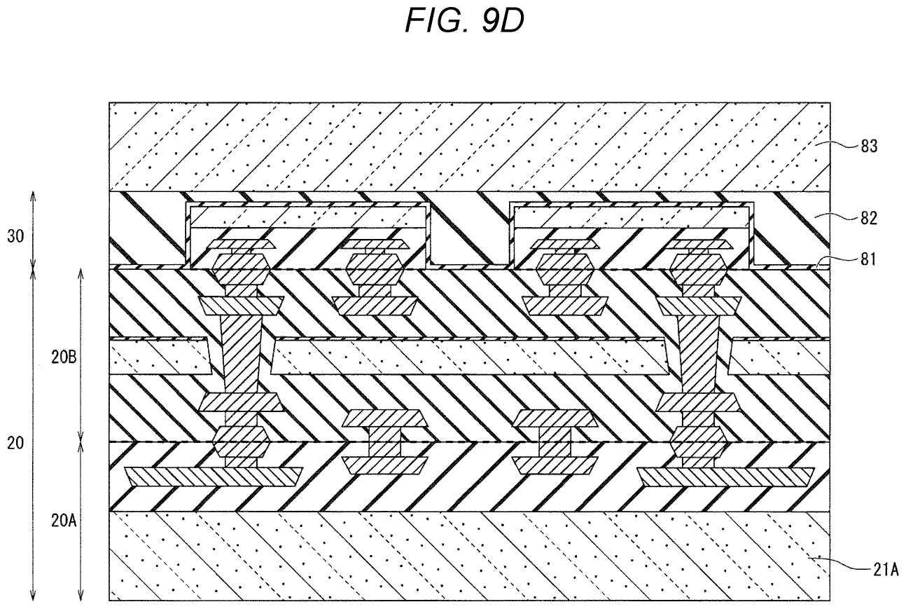

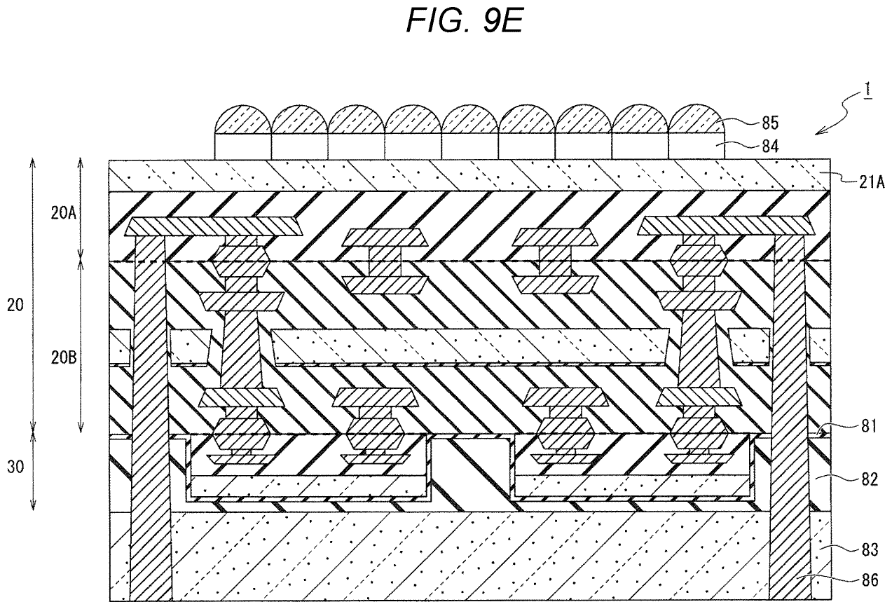

Hereinafter, a manufacturing method for the photodetection device 1 will be described with reference to FIGS. 9A to 9E. Note that, in the manufacturing method for a photodetection device 1 described below, a configuration of the photodetection device 1 is partially different from the configuration of the photodetection device 1 illustrated in FIGS. 4, 5B, and 5C. For example, in the manufacturing method for the photodetection device 1 described below, the number of the second semiconductor chips 30 is two. A storage circuit such as a memory is mounted in one of the chips, while the logic circuit 13, the circuit constituting artificial intelligence (AI), or the like is mounted in another chip. Furthermore, the first semiconductor chip 20 has a multilayer structure of a first semiconductor chip 20A and a first semiconductor chip 20B, and the above-described pixel region 2A and photoelectric conversion element PD are formed in the semiconductor layer 21 of the first semiconductor chip 20A. Furthermore, FIGS. 9A to 9E illustrate only one first semiconductor chip 20 before being singulated, among the plurality of first semiconductor chips 20 formed for each chip region CP on the semiconductor wafer W in FIG. 5A.

First, as illustrated in FIG. 9A, the semiconductor wafer W and the second semiconductor chip 30 are prepared. The semiconductor wafer W includes multiple chip regions CP (see FIG. 5B) which are regions to be divided into the first semiconductor chips 20, and has one surface as the first joint surface S1. The second semiconductor chip 30 has a size smaller than the chip region CP in plan view, and has one surface as the second joint surface S2. The first semiconductor chip 20 includes the sensing electrode 50 (not illustrated) facing the first region S1a on the first joint surface S1, the inspection electrode 60, and the connection wiring line 70 electrically connecting the sensing electrode 50 to the inspection electrode 60. Then, the second semiconductor chip 30 includes the pad electrode 40 (not illustrated) facing the second joint surface S2.

Then, the second semiconductor chip 30 and the first semiconductor chip 20 are aligned such that the pad electrode 40 (not illustrated) and the first sensing electrode 51 (not illustrated) overlap with each other. More specifically, the second semiconductor chip 30 and the chip region CP are aligned. Then, the second joint surface S2 of the second semiconductor chip 30 is bonded to the chip region CP, more specifically, the first region S1a.

The inspection as to whether or not the second semiconductor chip 30 is bonded to the chip region CP (first semiconductor chip 20) with a deviation amount smaller than a management value, that is, determination as to whether or not joint between the second semiconductor chip 30 and the chip region CP is good can be executed at a time when the step of bonding the second semiconductor chip 30 to the chip region CP is completed. At a time when the step of bonding the second semiconductor chip 30 to the chip region CP is completed, the inspection electrode 60 is exposed to the first joint surface S1. More specifically, the inspection electrode 60 is exposed to the second region S1b (see FIG. 5C). Therefore, it is possible to determine whether or not the second semiconductor chip 30 is bonded to the first semiconductor chip 20 with a deviation amount smaller than the management value, by performing a simple inspection of checking the presence or absence of electrical conduction between the exposed two inspection electrodes 60 by using the pair of probes P. Then, this inspection can be performed at any time while the inspection electrode 60 is exposed. That is, this inspection can be performed until before a step of stacking another material (for example, an insulating film or the like) on the exposed surface of the inspection electrode 60. Then, in order to distinguish a chip in which a deviation amount is equal to or larger than the management value from a chip in which a deviation amount is smaller than the management value, a position or the like on the semiconductor wafer W may be recorded.

Next, as illustrated in FIG. 9B, the semiconductor layer 31 of the second semiconductor chip 30 is thinned by a CMP method or the like. Then, as illustrated in FIG. 9C, an insulating film 81 and a planarization film 82 are laminated in this order so as to cover the exposed surface of the second semiconductor chip 30. The planarization film 82 is a resin or an inorganic film. In the present embodiment, a description will be given on the assumption that the planarization film 82 is silicon oxide deposited by a chemical vapor deposition (CVD) method.

Then, as illustrated in FIG. 9D, a support substrate 83 is bonded to the exposed surface of the planarization film 82. Thereafter, as illustrated in FIG. 9E, a semiconductor layer 21A of the first semiconductor chip 20 is thinned by a CMP method or the like, and a color filter 84, a microlens 85, and the like, but not limited thereto, are formed on an exposed surface of the thinned semiconductor layer 21A, for example. The microlens 85 condenses incident light on the semiconductor layer 21A. The color filter 84 performs color separation on incident light on the semiconductor layer 21A. The color filter 84 and the microlens 85 each are provided for every pixel 3. The color filter 84 and the microlens 85 are made containing, for example, a resin material.

Then, as illustrated in FIG. 9E, the support substrate 83 is thinned by a CMP method or the like, and a wiring line such as a through silicon via 86 is formed from the thinned exposed surface side of the support substrate 83, for example. In this manner, the photodetection device 1 is almost completed. Thereafter, by cutting the semiconductor wafer W along the scribe line SL (see FIG. 5B) to singulate the photodetection device 1, the semiconductor chip 2 is obtained.

### <<Principal Effects of First Embodiment>>

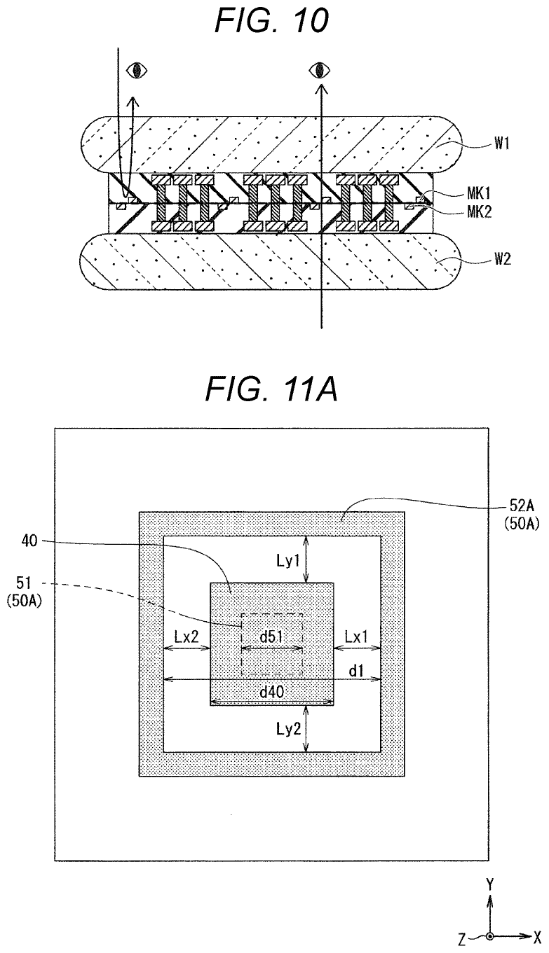

Hereinafter, a main effect of the first embodiment will be described. Before that, an example in which bonding is performed by a wafer-on-wafer (WoW) method will be described. In the example illustrated in FIG. 10, a wafer W1 and a wafer W2 each having an integrated circuit are joined by Wow. In a case of joining the wafer W1 and the wafer W2 by WOW, marks MK1 and MK2 for measuring misalignment in the bonding has been able to be provided on the scribe line. Since a scribe line is a region to be cut at the time of singulation, even if a wiring line or the like is provided, only few has been provided. Therefore, even in a case where misalignment of the bonding is optically measured using inspection light such as infrared light, it has been difficult for progress of the inspection light to be inhibited by the wiring line or the like. Therefore, misalignment of the bonding can be measured by a reflection method (left side of the page of FIG. 10) or a transmission method (right side of the page of FIG. 10) using inspection light such as infrared light.

However, in a case of forming the semiconductor chip 2 mounted with the photodetection device 1 by CoW (chip-on-wafer), most of the scribe line of the already singulated second semiconductor chip has been lost at the time of wafer cutting. Therefore, it has not been possible to provide a mark on the scribe line, for measuring misalignment of bonding.

Furthermore, a size of the second semiconductor chip in plan view may be smaller than that of the first semiconductor chip. Then, there has been a case where the second semiconductor chip is bonded so as to overlap with the pixel region 2A of the first semiconductor chip in plan view. The pixel region 2A of the first semiconductor chip is a region where many transistors T and wiring lines M are provided due to miniaturization and high density of the pixels 3. When the marks MK1 and MK2 for measuring misalignment of bonding are provided in the region overlapping with the region where many transistors T and wiring lines M are provided in plan view, there has been a possibility that the inspection light is blocked by the wiring line or the like. Furthermore, in order to prevent the inspection light from being blocked by the wiring line or the like, when a layout is adopted in which the wiring line or the like is not disposed in a region overlapping with the marks MK1 and MK2 in a thickness direction of the first semiconductor chip and the second semiconductor chip, there has been a possibility that a design load increases.

In this regard, in the photodetection device 1 according to the first embodiment of the present technology, the first semiconductor chip 20 includes the set 91 of the first sensing electrode 51, the first inspection electrode 61, and the first connection wiring line 71, and the set 92 of the second sensing electrode portion 52, the second inspection electrode 62, and the second connection wiring line 72, and the second semiconductor chip includes the pad electrode 40. Then, the pad electrode 40 electrically short-circuits or opens the set 91 and the set 92 depending on magnitude of misalignment of bonding between the first semiconductor chip 20 and the second semiconductor chip 30A, so that misalignment between the second semiconductor chip 30A and the first semiconductor chip 20 can be electrically detected.

Furthermore, in the photodetection device 1 according to the first embodiment of the present technology, the connection wiring line 70 may be simply routed only to the first semiconductor chip 20 out of the first semiconductor chip 20 and the second semiconductor chip 30A, so that an influence on the design can be suppressed.

Furthermore, in the photodetection device 1 according to the first embodiment of the present technology, the second sensing electrode 52 includes a plurality of the second sensing electrode portions 52 electrically separated from each other and arranged along a line surrounding the first sensing electrode 51. Then, the second sensing electrode portion 52 is disposed around the first sensing electrode 51 in four directions of the first sensing electrode 51. Therefore, by detecting whether or not there is a short circuit between the set 91 and one set among the plurality of sets 92, which direction the second semiconductor chip 30A is deviated in with respect to the first semiconductor chip 20 can be specified. More specifically, it is possible to specify which direction out of the +X direction, the −X direction, the +Y direction, and the −Y direction the second semiconductor chip 30A is deviated in with respect to the first semiconductor chip 20.

Furthermore, in the photodetection device 1 according to the first embodiment of the present technology, misalignment of bonding between the second semiconductor chip 30A and the first semiconductor chip 20 is not optically but electrically detected. Therefore, even in a case where the marks MK1 and MK2 cannot be disposed on the scribe line as in the case of forming the photodetection device 1 with CoW (chip-on-wafer), misalignment between the second semiconductor chip 30A and the first semiconductor chip 20 can be detected.

Furthermore, in the photodetection device 1 according to the first embodiment of the present technology, misalignment of the bonding between the second semiconductor chip 30A and the first semiconductor chip 20 is electrically detected without using the inspection light. Therefore, misalignment of bonding can be detected regardless of internal structures such as a wiring line of the first semiconductor chip 20 and the second semiconductor chip 30A.

Furthermore, in the photodetection device 1 according to the first embodiment of the present technology, some dummy pads DP are used as the inspection electrodes 60. Therefore, it is not necessary to change a mask used in a lithography step for the inspection electrode 60, which is advantageous in terms of a manufacturing cost.

Furthermore, in the photodetection device 1 according to the first embodiment of the present technology, by performing simple inspection of checking presence or absence of electrical conduction between the two exposed inspection electrodes 60 by using the pair of probes P, it is possible to determine whether or not the second semiconductor chip 30A is bonded to the first semiconductor chip 20 with a deviation amount smaller than a management value. Therefore, the inspection step can be suppressed from becoming complicated.

Furthermore, in the manufacturing method for the photodetection device 1 according to the first embodiment of the present technology, inspection as to whether or not the second semiconductor chip 30A is bonded to the chip region CP (first semiconductor chip 20) with a deviation amount smaller than a management value can be executed at a time when the step of bonding the second semiconductor chip 30A to the chip region CP is completed. Therefore, it is possible to immediately determine whether or not the misalignment amount of the bonding is smaller than the management value.

Note that the effect on the second semiconductor chip 30A described above should be interpreted as an effect on the second semiconductor chip 30 including the second semiconductor chips 30B and 30C. The same applies to each modification described below.

Furthermore, in FIG. 6A, all of the distance Lx1, the distance Lx2, the distance Ly1, and the distance Ly2, which are management values, have the same value, but at least some of the values may be different. More specifically, in a case where a margin of misalignment in one direction is smaller than a margin of misalignment in another direction, the management value in the one direction may be set to be smaller than the management value in the another direction. For example, in margins along the X direction, in a case where a margin in a right side direction in the page is smaller than a margin toward the left side in the page, the distance Lx1 may be set to be smaller than the distance Lx2. Furthermore, for example, in a case where a margin along the Y direction is smaller than a margin along the X direction, the management values (the distance Ly1 and the distance Ly2) along the Y direction may be set to be smaller than the management values (the distance Lx1 and the distance Lx2) along the X direction. In this manner, magnitude of each management value may simply be appropriately set according to magnitude of individual margin of misalignment of the photodetection device 1. Then, in order to make a difference in magnitude of the management values, a dimension in the X direction and a dimension in the Y direction of the pad electrode 40 may be provided in different sizes. Furthermore, in order to make a difference in magnitude of the management values, a distance between the second sensing electrode portion 52a and the second sensing electrode portion 52c opposed to each other with the first sensing electrode 51 interposed in between and a distance between the second sensing electrode portion 52b and the second sensing electrode portion 52d may be different distances.

### MODIFICATIONS OF FIRST EMBODIMENT

In the description below, modifications of the first embodiment are explained.

### Modification 1

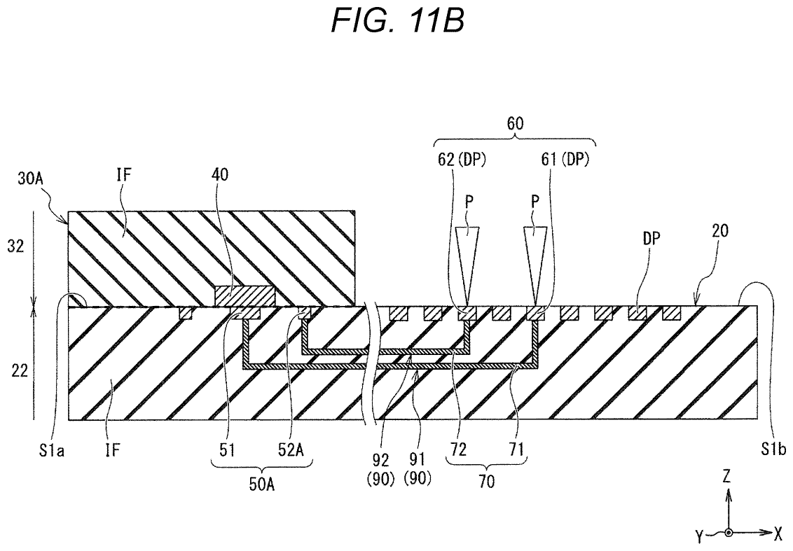

In the photodetection device 1 according to the first embodiment, the first semiconductor chip 20 includes the sensing electrode 50, but the present technology is not limited thereto. As illustrated in FIGS. 11A and 11B, in the photodetection device 1 according to Modification 1 of the first embodiment, the first semiconductor chip 20 may include a sensing electrode 50A instead of the sensing electrode 50.

The sensing electrode 50A includes the first sensing electrode 51 and a second sensing electrode 52A facing the first region S1a. As illustrated in FIG. 11A, the second sensing electrode 52A has a shape obtained by connecting a plurality of the second sensing electrode portions 52 to one. That is, the second sensing electrode 52A is a single member continuously surrounding the first sensing electrode 51 without interruption. More specifically, the second sensing electrode 52A is a band-shaped electrode continuous along an outer shape of a polygon (a square in the present modification) having the same number of sides as the pad electrode 40 in plan view. Furthermore, as illustrated in FIG. 11B, the first semiconductor chip 20 includes the second connection wiring line 72 that is provided in the wiring layer 22 and electrically connects the second sensing electrode 52A to the second inspection electrode 62. In the present modification, since the second sensing electrode 52A is a single member and is not divided into a plurality of parts, a configuration is sufficient in which one second inspection electrode 62 and one second connection wiring line 72 are provided. Then, as a result, the configuration is adopted in which one set 91 and one set 92 are provided.

Whether or not misalignment of bonding between the second semiconductor chip 30A and the first semiconductor chip 20 is smaller than a management value can be determined by checking presence or absence of electrical conduction between the set 91 and the set 92 by using the pair of probes P. More specifically, whether or not misalignment is smaller than the management value can be determined by checking presence or absence of electrical conduction between the first inspection electrode 61 and the second inspection electrode 62 by using the pair of probes P. In a case where it is confirmed that there is no electrical conduction between the first inspection electrode 61 and the second inspection electrode 62, it can be seen that the set 91 and the set 92 are electrically separated. As a result, it can be determined that the second semiconductor chip 30A has been bonded to the first semiconductor chip 20 with misalignment smaller than the management value. Whereas, in a case where it is confirmed that there is electrical conduction between the first inspection electrode 61 and the second inspection electrode 62, it can be seen that the set 91 and the set 92 are electrically short-circuited. As a result, it can be determined that the second semiconductor chip 30A has been bonded to the first semiconductor chip 20 with misalignment equal to or larger than the management value. Note that, in the present modification, the second sensing electrode 52A is a band-shaped electrode continuous along an outer shape of a polygon (a square in the present modification) having the same number of sides as the pad electrode 40. Therefore, it is possible to determine only that misalignment is equal to or larger than the management value, out of whether or not misalignment is equal to or larger than the management value and which direction the misalignment is in.

Effects similar to those of the photodetection device 1 according to the first embodiment described above can be achieved with the photodetection device 1 according to Modification 1 of the first embodiment.

Furthermore, in a case where it is only necessary to determine whether or not misalignment is equal to or larger than the management value, out of whether or not misalignment is equal to or larger than the management value and the direction of the misalignment, using the configuration of the photodetection device 1 according to Modification 1 of the first embodiment is sufficient. Since the photodetection device 1 according to Modification 1 of the first embodiment only needs to have one set 91 and one set 92, the number of second connection wiring lines 72 can be reduced as compared with the case of the first embodiment. Then, in the photodetection device 1 according to Modification 1 of the first embodiment, one first inspection electrode 61 and one second inspection electrode 62 are provided. More specifically, the number of the second inspection electrodes 62 is singular and not plural. Therefore, in the determination as to whether or not misalignment of bonding between the second semiconductor chip 30A and the first semiconductor chip 20 is smaller than the management value, presence or absence of electrical conduction between the first inspection electrode 61 and the second inspection electrode 62 is only required to be checked once without performing a plurality of times while changing the pair. As a result, the time and effort required for the inspection can be shortened.

### Modification 2

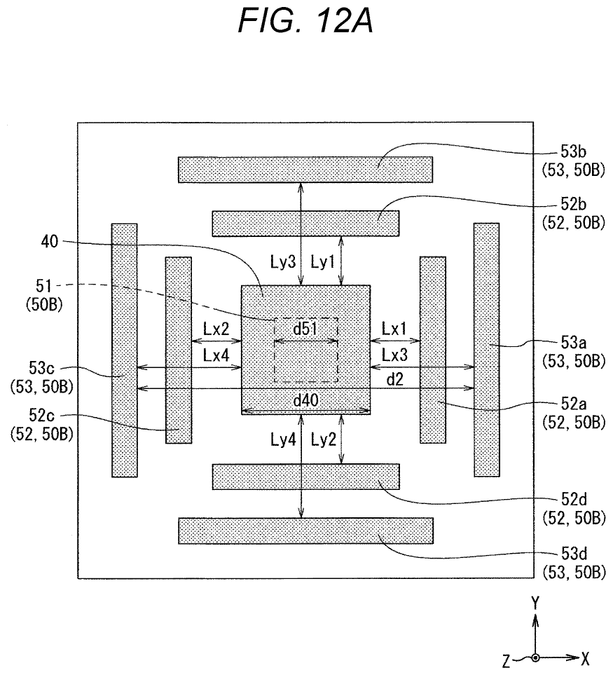

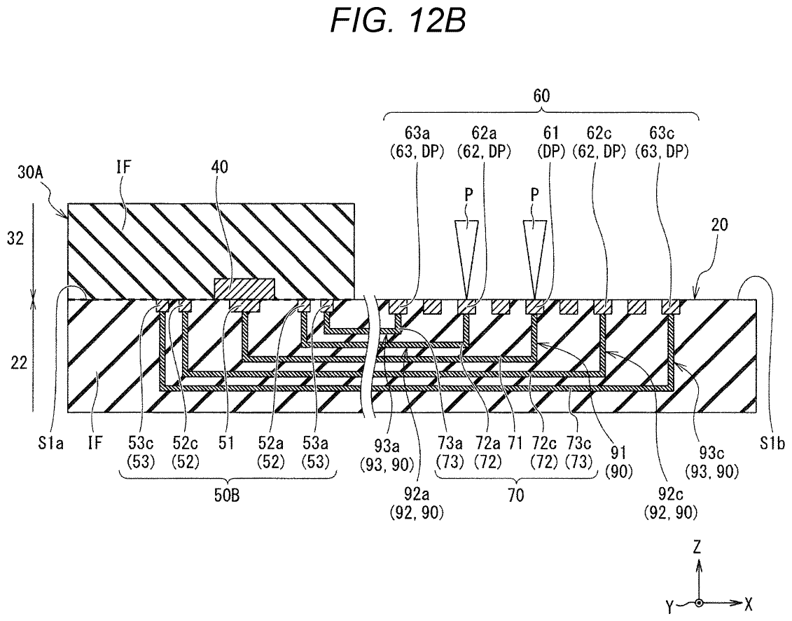

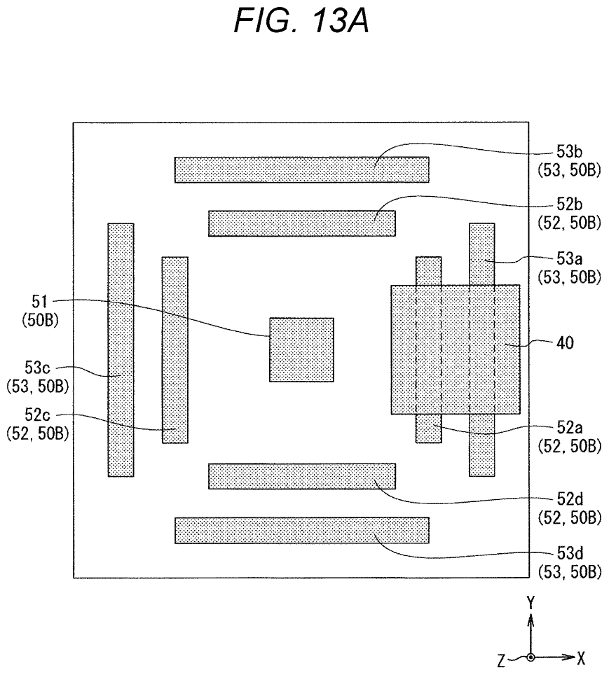

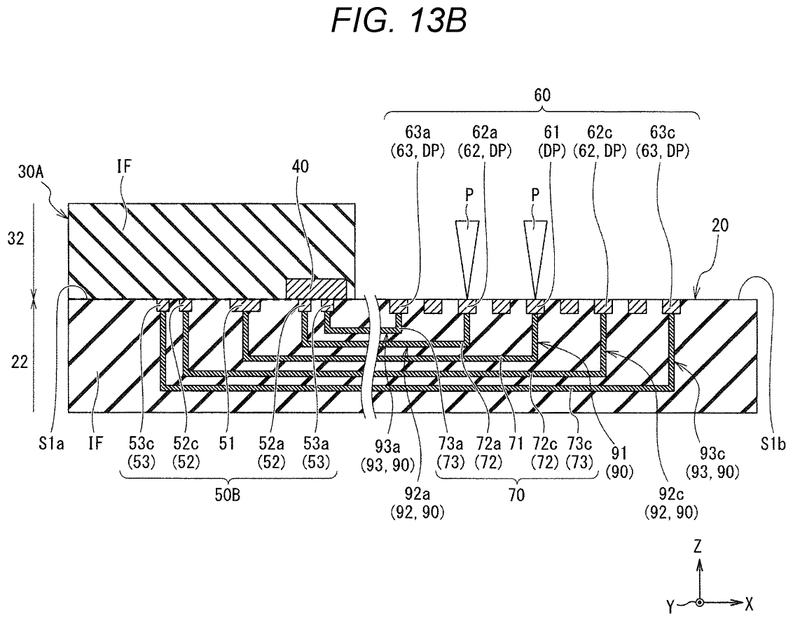

In the photodetection device 1 according to the first embodiment, the first semiconductor chip 20 includes the sensing electrode 50, but the present technology is not limited thereto. As illustrated in FIGS. 12A, 12B, 13A, and 13B, in the photodetection device 1 according to Modification 2 of the first embodiment, the first semiconductor chip 20 may include a sensing electrode 50B instead of the sensing electrode 50. Then, in the present modification, the management value described above is provided in two stages of a first management value and a second management value.

The sensing electrode 50B includes the first sensing electrode 51, the second sensing electrode 52, and a third sensing electrode 53 that faces the first region S1a and surrounds the second sensing electrode 52. The first sensing electrode 51 and the second sensing electrode 52 are electrically separated from the third sensing electrode 53.

The third sensing electrode 53 includes a plurality of third sensing electrode portions electrically separated from each other and arranged along a line surrounding the second sensing electrode 52. More specifically, the third sensing electrode 53 includes four third sensing electrode portions 53a, 53b, 53c, and 53d. Note that, the plurality of (four in the present embodiment) third sensing electrode portions 53a, 53b, 53c, and 53d may be collectively referred to as the third sensing electrode 53. Furthermore, the third sensing electrode portions 53a, 53b, 53c, and 53d each may be referred to as a third sensing electrode portion 53 in a case of not being distinguished from each other.

The third sensing electrode portion 53 is, for example, a rectangular electrode. The third sensing electrode portion 53 is an oblong electrode in the present embodiment. The third sensing electrode portions 53 are provided in equal number to the number of sides of the pad electrode 40 (four in the present embodiment). More specifically, the third sensing electrode portions 53 are provided in equal number to the number of sides of the pad electrode 40 and the first sensing electrode 51 and the number of portions of the second sensing electrode 52. The third sensing electrode portion 53 is disposed around the first sensing electrode 51 in four directions (+X direction, −X direction, +Y direction, and −Y direction) of the first sensing electrode 51 with the second sensing electrode portion 52 interposed in between. More specifically, the third sensing electrode portions 53a and 53c are disposed along the X direction with the first sensing electrode 51 and the second sensing electrode portions 52a and 52c interposed in between. Then, the third sensing electrode portions 53a and 53c are disposed such that long sides thereof are opposed to each other, and the opposed long sides are parallel to each other. Then, the third sensing electrode portions 53b and 53d are disposed with the first sensing electrode 51 and the second sensing electrode portions 52b and 52d interposed in between along the Y direction orthogonal to the X direction. Then, the third sensing electrode portions 53b and 53d are disposed such that long sides thereof are opposed to each other, and the opposed long sides are parallel to each other. Furthermore, the third sensing electrode portions 53 are separated from each other at diagonal positions of the first sensing electrode 51.

A pair of the second sensing electrode portion 52 and the third sensing electrode portion 53 disposed in the same direction among the four directions starting from the first sensing electrode 51 are disposed such that long sides thereof are parallel to each other. Then, a distance between the second sensing electrode portion 52 and the third sensing electrode portion 53 disposed in the same direction among the four directions is equal in all the pairs located in the four directions. More specifically, a distance between the second sensing electrode portion 52a and the third sensing electrode portion 53a, a distance between the second sensing electrode portion 52b and the third sensing electrode portion 53b, a distance between the second sensing electrode portion 52c and the third sensing electrode portion 53c, and a distance between the second sensing electrode portion 52d and the third sensing electrode portion 53d are equal.

A distance between the third sensing electrode portion 53a and the third sensing electrode portion 53c opposed to each other with the first sensing electrode 51 and the second sensing electrode portions 52a and 52c interposed in between is the same as a distance between the third sensing electrode portion 53b and the third sensing electrode portion 53d opposed to each other with the first sensing electrode 51 and the second sensing electrode portions 52b and 52d interposed in between. Here, the distance is referred to as a distance d2. Furthermore, the distance d2 can be defined as d2=d40+Lx3+Lx4 using distances Lx3 and Lx4 described later. Furthermore, the distance d2 can be defined as d2=d40+Ly3+Ly4 using distances Ly3 and Ly4 described later.

FIGS. 12A and 12B illustrate a state in which the second semiconductor chip 30A is bonded to the first semiconductor chip 20 with ideal alignment designed. In the ideal state as illustrated in FIG. 12A, the third sensing electrode portion 53 is disposed such that a long side thereof is opposed to each side of the pad electrode 40. Then, the third sensing electrode portion 53 is disposed such that a long side opposed to the pad electrode 40 is parallel to a side of the pad electrode 40. Furthermore, in the ideal state described above, the distance Lx3 between the pad electrode 40 and the third sensing electrode portion 53a is equal to the distance Lx4 between the pad electrode 40 and the third sensing electrode portion 53c (Lx3=Lx4). Similarly, the distance Ly3 between the pad electrode 40 and the third sensing electrode portion 53b is equal to the distance Ly4 between the pad electrode 40 and the third sensing electrode portion 53d (Ly3=Ly4). Moreover, in the present embodiment, all of the distance Lx3, the distance Lx4, the distance Ly3, and the distance Ly4 have the same value (Lx3=Lx4=Ly3=Ly4). Then, the distances Lx3, Lx4, Ly3, and Ly4 are second management values of misalignment between the second semiconductor chip 30A and the first semiconductor chip 20, and may be referred to as management values Lx3, Lx4, Ly3, and Ly4. More specifically, Lx3 and Lx4 are second management values of misalignment in the X direction, and Ly3 and Ly4 are second management values of misalignment in the Y direction. Then, the distances Lx1, Lx2, Ly1, and Ly2 are referred to as first management values, and the first management value and the second management value are distinguished from each other. The first management value and the second management value are simply referred to as management values in a case of not being distinguished from each other. The second management value is set to be larger than the first management value. In the present modification, the second management value is set to be twice as large as the first management value, but magnitude of the second management value is not limited thereto, and may be set according to a margin of misalignment in bonding between the second semiconductor chip 30A and the first semiconductor chip 20.

As illustrated in FIG. 12B, the inspection electrode 60 includes the first inspection electrode 61, the second inspection electrode 62, and a third inspection electrode 63. Note that, the first inspection electrode 61, the second inspection electrode 62, and the third inspection electrode 63 are simply referred to as the inspection electrode 60 in a case of not being distinguished from each other. A plurality of third inspection electrodes 63 is provided. More specifically, the third inspection electrodes 63 are provided in equal number to the number of the third sensing electrode portions 53 (four in the present embodiment). The third inspection electrodes 63 are electrically separated from each other. FIG. 12B illustrates only a third inspection electrode 63a and a third inspection electrode 63c among the plurality of third inspection electrodes 63. The plurality of third inspection electrodes 63 such as the third inspection electrode 63a and the third inspection electrode 63c is simply referred to as the third inspection electrode 63 in a case of not being distinguished from each other.

The connection wiring line 70 includes the first connection wiring line 71 that electrically connects the first sensing electrode 51 to the first inspection electrode 61, the second connection wiring line 72 that electrically connects the second sensing electrode 52 to the second inspection electrode 62, and a third connection wiring line 73 that electrically connects the third sensing electrode 53 to the third inspection electrode 63. The first connection wiring line 71, the second connection wiring line 72, and the third connection wiring line 73 are simply referred to as the connection wiring line 70 in a case of not being distinguished from each other. A plurality of the third connection wiring lines 73 is provided. More specifically, the third connection wiring lines 73 are provided in equal number to the number of the third sensing electrode portions 53 (four in the present embodiment). The third connection wiring lines 73 are electrically separated from each other. Among the plurality of third connection wiring lines 73, FIG. 12B illustrates only a third connection wiring line 73a that electrically connects the third sensing electrode 53a to the third inspection electrode 63a and a third connection wiring line 73c that electrically connects the third sensing electrode 53c to the third inspection electrode 63c. The plurality of third connection wiring lines 73 such as the third connection wiring line 73a and the third connection wiring line 73c is simply referred to as the third connection wiring line 73 in a case of not being distinguished from each other.

As described above, the third inspection electrode 63 and the third connection wiring line 73 are provided for each of the third sensing electrode portions 53. That is, a plurality of sets 93 of the third sensing electrode portion 53, the third inspection electrode 63, and the third connection wiring line 73 is provided. Then, the sets 93 are electrically separated from each other. FIG. 12B illustrates a set 93a of the third sensing electrode portion 53a, the third inspection electrode 63a, and the third connection wiring line 73a, and a set 93c of the third sensing electrode portion 53c, the third inspection electrode 63c, and the third connection wiring line 73c. Note that, a plurality of sets such as the set 93a and the set 93c is simply referred to as the set 93 in a case of not being distinguished from each other.

The set 91, the set 92, and the set 93 are electrically separated from each other. Note that, the set 91, the set 92, and the set 93 are simply referred to as a set 90 in a case of not being distinguished from each other.

Whether or not misalignment of bonding between the second semiconductor chip 30A and the first semiconductor chip 20 is equal to or larger than the second management value can be determined by checking presence or absence of electrical conduction between the set 92 and the set 93 by using the pair of probes P. More specifically, whether or not misalignment is equal to or larger than the second management value can be determined by checking presence or absence of electrical conduction between a pair of the second inspection electrode 62 and the third inspection electrode 63 by using the pair of probes P while changing the pair, since the plurality of second inspection electrodes 62 and the plurality of third inspection electrodes 63 are exposed to the second region S1b. Hereinafter, the determination will be described in detail.

With reference to FIGS. 13A and 13B, a case will be described in which the second semiconductor chip 30A is bonded to the first semiconductor chip 20 with misalignment equal to or larger than the second management value beyond the first management. For example, as illustrated in FIGS. 13A and 13B, it is assumed that the second semiconductor chip 30A is deviated to the right side in the page and bonded to the first semiconductor chip 20. More specifically, it is assumed that the second semiconductor chip 30A is bonded to the first semiconductor chip 20 with misalignment equal to or larger than the second management value Lx3 toward the right side of the page. The pad electrode 40 is relatively deviated to the right side in the page, and is connected to both the second sensing electrode portion 52a and the third sensing electrode portion 53a to short-circuit the two. It is assumed that the set 92a and the set 93a are short-circuited as a result.

Whether or not the second semiconductor chip 30A is bonded to the first semiconductor chip 20 with misalignment equal to or larger than the second management value is determined by checking presence or absence of electrical conduction between one second inspection electrode 62 and one third inspection electrode 63 by using the pair of probes P while changing the pair. Here, the second inspection electrode 62 and the third inspection electrode 63 forming a pair are, for example, electrodes connected to one and another of the second sensing electrode portion 52 and the third sensing electrode portion 53 disposed in the same direction starting from the first sensing electrode 51. Then, when checking the presence or absence of electrical conduction between one second inspection electrode 62 and one third inspection electrode 63 while changing the pair, it is detected that only a pair of the second inspection electrode 62a and the third inspection electrode 63a illustrated in FIG. 13B has electrical conduction, that is, is short-circuited. As a result, it can be seen that only the set 92a and the set 93a are short-circuited. Then, as a result, it can be determined that the second semiconductor chip 30A is bonded to the first semiconductor chip 20 with misalignment equal to or larger than the second management value Lx3 toward the right side (+X direction) in the page. In this manner, it is possible to detect whether or not the second semiconductor chip 30A is bonded to the first semiconductor chip 20 with misalignment equal to or larger than the second management value. Furthermore, since the third sensing electrode 53 includes the four third sensing electrode portions 53a, 53b, 53c, and 53d, which direction the second semiconductor chip 30A is deviated in with respect to the first semiconductor chip 20 can be specified. More specifically, it is possible to specify which direction out of the right side (+X direction) in the page, the left side (−X direction) in the page, the upper side (+Y direction) in the page, and the lower side (−Y direction) in the page the second semiconductor chip 30A is deviated in with respect to the first semiconductor chip 20.

Note that, in a case where electrical conduction is not detected in any pair, it can be determined that the second semiconductor chip 30A is bonded to the first semiconductor chip 20 with misalignment smaller than the second management value.

Effects similar to those of the photodetection device 1 according to the first embodiment described above can also be achieved with the photodetection device 1 according to Modification 2 of the first embodiment.

Furthermore, in the photodetection device 1 according to Modification 2 of the first embodiment, the management value is provided in two stages of the first management value and the second management value. Therefore, a degree of a misalignment amount of the second semiconductor chip 30A with respect to the first semiconductor chip 20 can be specified more finely.

Note that, in FIG. 12A, all of the distance Lx3, the distance Lx4, the distance Ly3, and the distance Ly4, which are management values, have the same value, but at least some of the values may be different.

### Modification 3

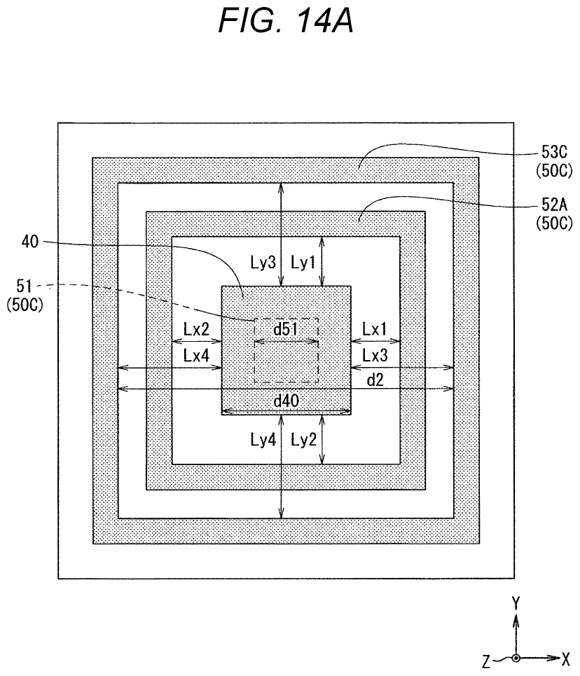

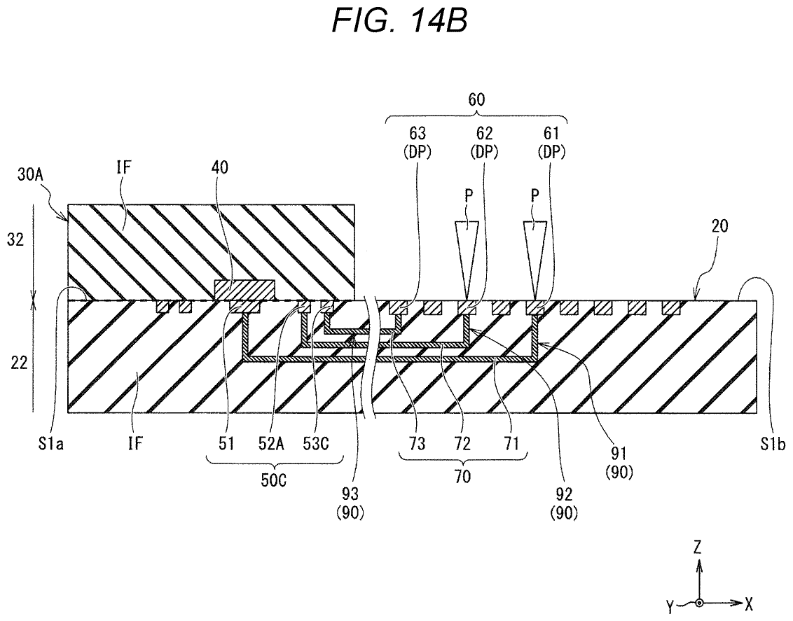

In the photodetection device 1 according to the first embodiment, the first semiconductor chip 20 includes the sensing electrode 50, but the present technology is not limited thereto. As illustrated in FIGS. 14A and 14B, in the photodetection device 1 according to Modification 3 of the first embodiment, the first semiconductor chip 20 may include a sensing electrode 50C instead of the sensing electrode 50.

The sensing electrode 50C includes the first sensing electrode 51, the second sensing electrode 52A, and a third sensing electrode 53C. As illustrated in FIG. 14A, the third sensing electrode 53C has a shape obtained by connecting a plurality of third sensing electrode portions 53 to one. That is, the third sensing electrode 53C is a single member continuously surrounding the second sensing electrode 52A without interruption. More specifically, the third sensing electrode 53C is a band-shaped electrode continuous along an outer shape of a polygon (a square in the present modification) having the same number of sides as the pad electrode 40 in plan view. Furthermore, as illustrated in FIG. 14B, the first semiconductor chip 20 includes the third connection wiring line 73 that is provided in the wiring layer 22 and electrically connects the third sensing electrode 53C to the third inspection electrode 63. In the present modification, since the third sensing electrode 53C is a single member and is not divided into a plurality of parts, a configuration is sufficient in which one third inspection electrode 63 and one third connection wiring line 73 are provided. Then, as a result, the configuration is adopted in which one set 91, one set 92, and one set 93 are provided.

Whether or not misalignment of bonding between the second semiconductor chip 30A and the first semiconductor chip 20 is equal to or larger than the second management value can be determined by checking presence or absence of electrical conduction between the set 92 and the set 93 by using the pair of probes P. More specifically, whether or not misalignment is equal to or larger than the second management value can be determined by checking presence or absence of electrical conduction between the second inspection electrode 62 and the third inspection electrode 63 by using the pair of probes P. In a case where it is confirmed that there is no electrical conduction between the second inspection electrode 62 and the third inspection electrode 63, it can be seen that the set 92 and the set 93 are electrically separated. As a result, it can be determined that the second semiconductor chip 30A has been bonded to the first semiconductor chip 20 with misalignment smaller than the second management value. Whereas, in a case where it is confirmed that there is electrical conduction between the second inspection electrode 62 and the third inspection electrode 63, it can be seen that the set 92 and the set 93 are electrically short-circuited. As a result, it can be determined that the second semiconductor chip 30A has been bonded to the first semiconductor chip 20 with misalignment equal to or larger than the second management value. Note that, in the present modification, the third sensing electrode 53C is a band-shaped electrode continuous along an outer shape of a polygon (a square in the present modification) having the same number of sides as the pad electrode 40. Therefore, it is possible to determine only whether or not the misalignment is equal to or larger than the second management value, out of whether or not misalignment is equal to or larger than the second management value and which direction the misalignment is in.

Effects similar to those of the photodetection device 1 according to the first embodiment described above and the photodetection device 1 according to Modification 2 of the first embodiment described above can be achieved with the photodetection device 1 according to Modification 3 of the first embodiment.

Furthermore, in a case where it is only necessary to determine whether or not misalignment is equal to or larger than the second management value, out of whether or not misalignment is equal to or larger than the second management value and the direction of the misalignment, using the configuration of the photodetection device 1 according to Modification 3 of the first embodiment is sufficient. Effects similar to those of the photodetection device 1 according to Modification 1 of the first embodiment described above can also be achieved with the photodetection device 1 according to Modification 3 of the first embodiment.

### Modification 4

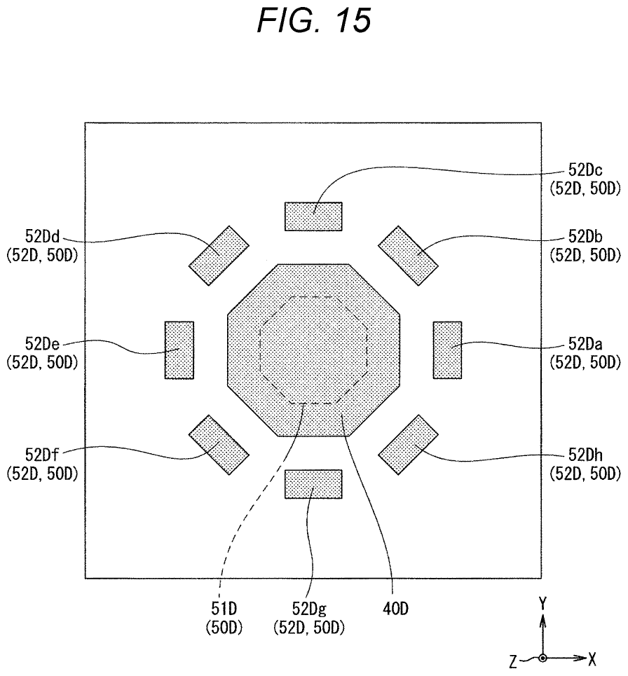

In the photodetection device 1 according to the first embodiment, the first semiconductor chip 20 includes the sensing electrode 50, and the second semiconductor chip 30A includes the pad electrode 40, but the present technology is not limited thereto. As illustrated in FIG. 15, in the photodetection device 1 according to Modification 4 of the first embodiment, the first semiconductor chip 20 may include a sensing electrode 50D, and the second semiconductor chip 30A may include a pad electrode 40D.

The pad electrode 40D is an octagonal electrode facing the second joint surface S2 in plan view. The sensing electrode 50D includes a first sensing electrode 51D and a second sensing electrode 52D that face the first region S1a. The first sensing electrode 51D is an electrode having a polygonal shape with the same number of sides as the pad electrode 40D in plan view, that is, an octagonal electrode.

The second sensing electrode 52D includes a plurality of second sensing electrode portions electrically separated from each other and arranged along a line surrounding the first sensing electrode 51D. More specifically, the second sensing electrode 52D includes eight second sensing electrode portions 52Da, 52Db, 52Dc, 52Dd, 52De, 52Df, 52Dg, and 52Dh. Note that, the plurality of (eight in the present embodiment) second sensing electrode portions may be collectively referred to as the second sensing electrode 52D. Furthermore, the second sensing electrode portion 52Da to the second sensing electrode portion 52Dh each may be referred to as a second sensing electrode portion 52D in a case of not being distinguished from each other.

The second sensing electrode portion 52D is, for example, a rectangular electrode. The second sensing electrode portion 52D is an oblong electrode in the present embodiment. The second sensing electrode portions 52D are provided in equal number to the number of sides of the pad electrode 40D (eight in the present embodiment). More specifically, the second sensing electrode portions 52D are provided in equal number to the number of sides of the pad electrode 40D and the first sensing electrode 51D. The second sensing electrode portion 52D is disposed around the first sensing electrode 51 in eight directions of the first sensing electrode 51.

Furthermore, in the present embodiment, since the first sensing electrode 51D is a polygonal electrode having the same number of sides as the pad electrode 40D, the second sensing electrode portion 52D is disposed such that a long side thereof is opposed to each side of the first sensing electrode 51D. Then, the second sensing electrode portion 52D is disposed such that a long side opposed to the first sensing electrode 51D is parallel to a side of the first sensing electrode 51D. Furthermore, the second sensing electrode portions 52D are separated from each other at diagonal positions of the first sensing electrode 51D. Each of the second sensing electrode portion 52Da to the second sensing electrode portion 52Dh is provided at a position equidistant from the first sensing electrode 51D.

As illustrated in FIG. 15, in a state where the second semiconductor chip 30A is bonded to the first semiconductor chip 20 with ideal alignment designed, the second sensing electrode portion 52D is disposed such that a long side thereof is opposed to each side of the pad electrode 40D. Then, the second sensing electrode portion 52D is disposed such that a long side opposed to the pad electrode 40D is parallel to a side of the pad electrode 40D.

Effects similar to those of the photodetection device 1 according to the first embodiment described above can also be achieved with the photodetection device 1 according to Modification 4 of the first embodiment.

Furthermore, in the photodetection device 1 according to Modification 4 of the first embodiment, the second sensing electrode portion 52D is disposed around the first sensing electrode 51D in eight directions of the first sensing electrode 51D. Therefore, which direction the second semiconductor chip 30A is deviated in with respect to the first semiconductor chip 20 can be specified. More specifically, it is possible to specify which direction out of an oblique (diagonal) direction (+X+Y direction, −X+Y direction, +X−Y direction, and −X−Y direction) the second semiconductor chip 30A is deviated in with respect to the first semiconductor chip 20, in addition to the horizontal direction (+X direction and −X direction) and the vertical direction (+Y direction and −Y direction) in the page. As a result, the direction of the misalignment can be specified more finely.

### Modification 5

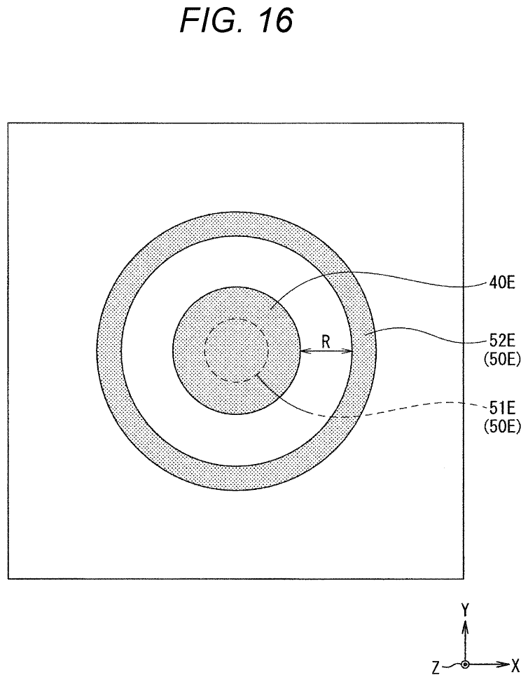

In the photodetection device 1 according to the first embodiment, the first semiconductor chip 20 includes the sensing electrode 50, but the present technology is not limited thereto. As illustrated in FIG. 16, in the photodetection device 1 according to Modification 5 of the first embodiment, the first semiconductor chip 20 may include a sensing electrode 50E instead of the sensing electrode 50, and the second semiconductor chip 30A may include a pad electrode 40E instead of the pad electrode 40.

The pad electrode 40E is an electrode that faces the second joint surface S2 and is a circular electrode in plan view. The sensing electrode 50E includes a first sensing electrode 51E and a second sensing electrode 52E that face the first region S1a. The first sensing electrode 51E is a circular electrode in plan view similarly to the pad electrode 40. The second sensing electrode 52E is an annular electrode, and a center of an inner circle or an outer circle overlaps with a center of the first sensing electrode 51E. More specifically, the second sensing electrode 52E is an annular electrode concentric with the first sensing electrode 51E.

FIG. 16 illustrates a positional relationship between the pad electrode 40E and the sensing electrode 50E in a state where the second semiconductor chip 30A is bonded to the first semiconductor chip 20 with ideal alignment designed. In this state, the second sensing electrode 52E is an annular ring concentric with the pad electrode 40E. Then, a distance between an outer periphery of the pad electrode 40E and an inner periphery of the second sensing electrode 52E is a distance R. The distance R is a management value of misalignment between the second semiconductor chip 30A and the first semiconductor chip 20, and may be referred to as a management value R.

Effects similar to those of the photodetection device 1 according to the first embodiment described above can also be achieved with the photodetection device 1 according to Modification 5 of the first embodiment.

Furthermore, in the photodetection device 1 according to Modification 5 of the first embodiment, since the second sensing electrode 52E is an annular electrode, the same management value R can be set in all directions.

### Modification 6

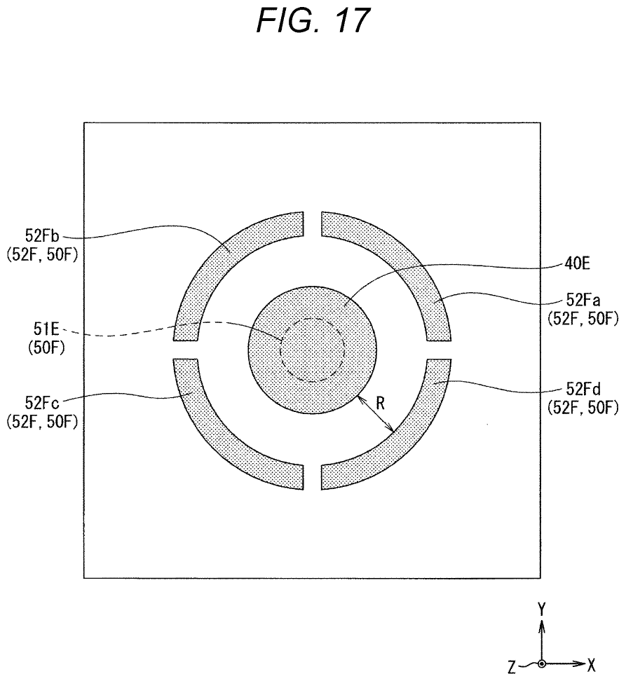

In the photodetection device 1 according to the first embodiment, the first semiconductor chip 20 includes the sensing electrode 50, but the present technology is not limited thereto. As illustrated in FIG. 17, in the photodetection device 1 according to Modification 6 of the first embodiment, the first semiconductor chip 20 may include a sensing electrode 50F instead of the sensing electrode 50, and the second semiconductor chip 30A may include the pad electrode 40E instead of the pad electrode 40.

The sensing electrode 50F includes a plurality of second sensing electrode portions electrically separated from each other and arranged along a line surrounding the first sensing electrode 51E. More specifically, a second sensing electrode 52F includes four second sensing electrode portions 52Fa, 52Fb, 52Fc, and 52Fd. Note that, the plurality of (four in the present embodiment) second sensing electrode portions 52Fa, 52Fb, 52Fc, and 52Fd may be collectively referred to as the second sensing electrode 52F. Furthermore, the second sensing electrode portions 52Fa, 52Fb, 52Fc, and 52Fd each may be referred to as a second sensing electrode portion 52F in a case of not being distinguished from each other. The second sensing electrode 52F has a shape obtained by dividing the sensing electrode 50E described above into a plurality of the second sensing electrode portions 52F. More specifically, the second sensing electrode 52F has a shape obtained by dividing the sensing electrode 50E described above into four second sensing electrode portions 52F along the X direction and the Y direction.

The second sensing electrode portion F52 is disposed around the first sensing electrode 51E in each of four oblique directions (+X+Y direction, −X+Y direction, −X−Y direction, and +X−Y direction) of the first sensing electrode 51. More specifically, around the first sensing electrode 51E, the second sensing electrode portion 52Fa is disposed in the +X+Y direction, the second sensing electrode portion 52Fb is disposed in the −X+Y direction, the second sensing electrode portion 52Fc is disposed in the −X−Y direction, and the second sensing electrode portion 52Fd is disposed in the +X−Y direction.

Effects similar to those of the photodetection device 1 according to the first embodiment described above and the photodetection device 1 according to Modification 5 of the first embodiment described above can be achieved with the photodetection device 1 according to Modification 6 of the first embodiment.

Furthermore, in the photodetection device 1 according to Modification 6 of the first embodiment, it is possible to specify which one of the oblique directions, more specifically, the +X+Y direction, the −X+Y direction, the −X−Y direction, and the +X−Y direction the second semiconductor chip 30A is deviated in with respect to the first semiconductor chip 20.

### Modification 7

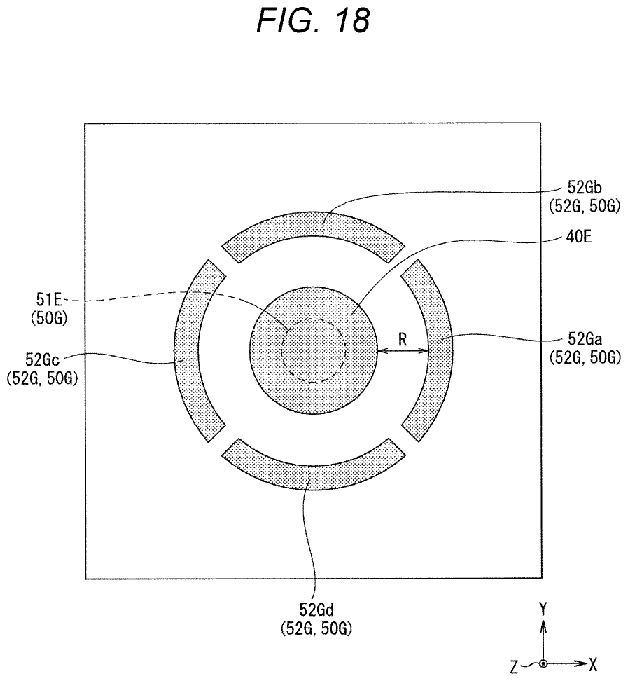

In the photodetection device 1 according to the first embodiment, the first semiconductor chip 20 includes the sensing electrode 50, but the present technology is not limited thereto. As illustrated in FIG. 18, in the photodetection device 1 according to Modification 7 of the first embodiment, the first semiconductor chip 20 may include a sensing electrode 50G instead of the sensing electrode 50, and the second semiconductor chip 30A may include the pad electrode 40E instead of the pad electrode 40.

The sensing electrode 50G includes a plurality of second sensing electrode portions electrically separated from each other and arranged along a line surrounding the first sensing electrode 51E. More specifically, a second sensing electrode 52G includes four second sensing electrode portions 52Ga, 52Gb, 52Gc, and 52Gd. Note that, the plurality of (four in the present embodiment) second sensing electrode portions 52Ga, 52Gb, 52Gc, and 52Gd may be collectively referred to as the second sensing electrode 52G. Furthermore, the second sensing electrode portions 52Ga, 52Gb, 52Gc, and 52Gd each may be referred to as a second sensing electrode portion 52G in a case of not being distinguished from each other. The second sensing electrode 52G has a shape obtained by dividing the sensing electrode 50E described above into a plurality of the second sensing electrode portions 52G. More specifically, the second sensing electrode 52G has a shape obtained by dividing the sensing electrode 50E described above into four second sensing electrode portions 52G along an oblique direction, more specifically, along a direction forming +45 degrees between with the X direction and a direction forming −45 degrees between with the X direction.

The second sensing electrode portion F52 is disposed around the first sensing electrode 51E in each of four directions (+X direction, +Y direction, −X direction, and −Y direction) of the first sensing electrode 51. More specifically, around the first sensing electrode 51E, the second sensing electrode portion 52Ga is disposed in the X direction, the second sensing electrode portion 52Gb is disposed in the +Y direction, the second sensing electrode portion 52Gc is disposed in the −X direction, and the second sensing electrode portion 52Gd is disposed in the −Y direction.

Effects similar to those of the photodetection device 1 according to the first embodiment described above and the photodetection device 1 according to Modification 5 of the first embodiment described above can be achieved with the photodetection device 1 according to Modification 7 of the first embodiment.

Furthermore, in the photodetection device 1 according to Modification 7 of the first embodiment, it is possible to specify which direction out of the +X direction, the +Y direction, the −X direction, and the −Y direction the second semiconductor chip 30A is deviated in with respect to the first semiconductor chip 20.

### Modification 8

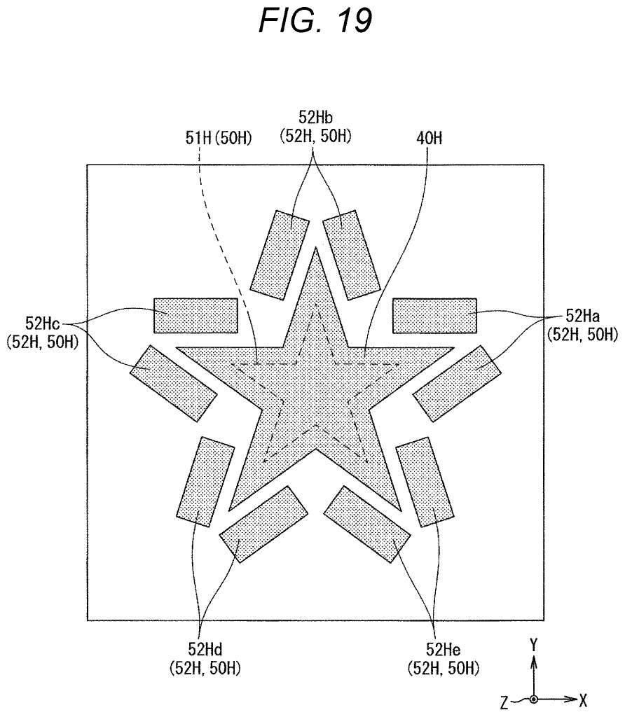

In the photodetection device 1 according to the first embodiment, the first semiconductor chip 20 includes the sensing electrode 50, but the present technology is not limited thereto. As illustrated in FIG. 19, in the photodetection device 1 according to Modification 8 of the first embodiment, the first semiconductor chip 20 may include a sensing electrode 50H, and the second semiconductor chip 30A may include a pad electrode 40H.

The pad electrode 40H is an electrode that faces the second joint surface S2 and has a re-entrant polygonal shape in plan view. More specifically, the pad electrode 40H is an electrode having a five-corner star polygonal shape in plan view. The sensing electrode 50H includes a first sensing electrode 51H and a second sensing electrode 52H that face the first region S1a. Similarly to the pad electrode 40H, the first sensing electrode 51H is an electrode having a re-entrant polygonal shape in plan view, more specifically, an electrode having a corner star polygonal shape.

The second sensing electrode 52H includes a plurality of second sensing electrode portions electrically separated from each other and arranged along a line surrounding the first sensing electrode 51H. More specifically, the second sensing electrode 52H includes five second sensing electrode portions 52Ha, 52Hb, 52Hc, 52Hd, and 52He. Note that, the plurality of second sensing electrode portions may be collectively referred to as the second sensing electrode 52H. Furthermore, the second sensing electrode portion 52Ha to the second sensing electrode portion 52He each may be referred to as a second sensing electrode portion 52H in a case of not being distinguished from each other.

Each of the second sensing electrode portions 52H has two electrically separated electrodes, for example, two rectangular electrodes. The rectangular electrodes included in the second sensing electrode portion 52H are arranged along a line surrounding the first sensing electrode 51H. More specifically, the two rectangular electrodes included in the second sensing electrode portion 52H are disposed so as to be opposed to two sides constituting a protruding corner of the first sensing electrode 51H. The two rectangular electrodes are disposed at positions equidistant from the two sides described above.

As illustrated in FIG. 19, in a state where the second semiconductor chip 30A is bonded to the first semiconductor chip 20 with ideal alignment designed, the two rectangular electrodes of the second sensing electrode portion 52H are disposed such that long sides thereof is opposed to the two sides constituting the protruding corners of the pad electrode 40H. Then, the rectangular electrode is disposed such that a long side opposed to the pad electrode 40H is parallel to a side of the pad electrode 40H.

Effects similar to those of the photodetection device 1 according to the first embodiment described above can also be achieved with the photodetection device 1 according to Modification 8 of the first embodiment.

### Modification 9

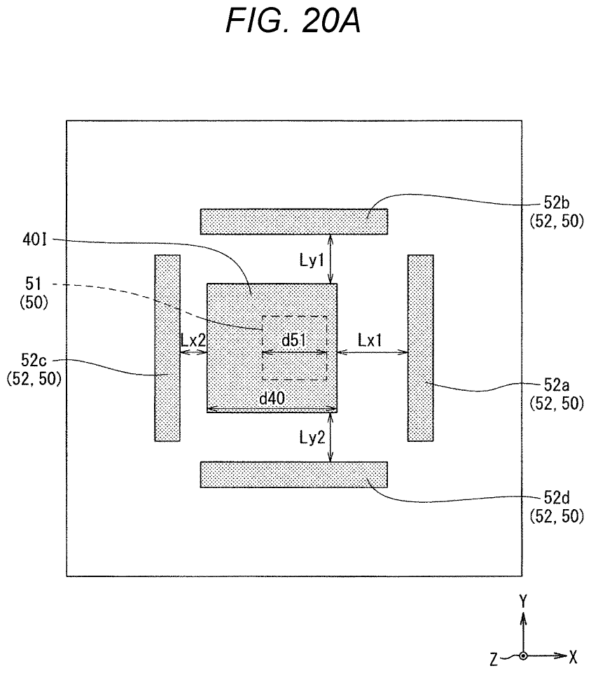

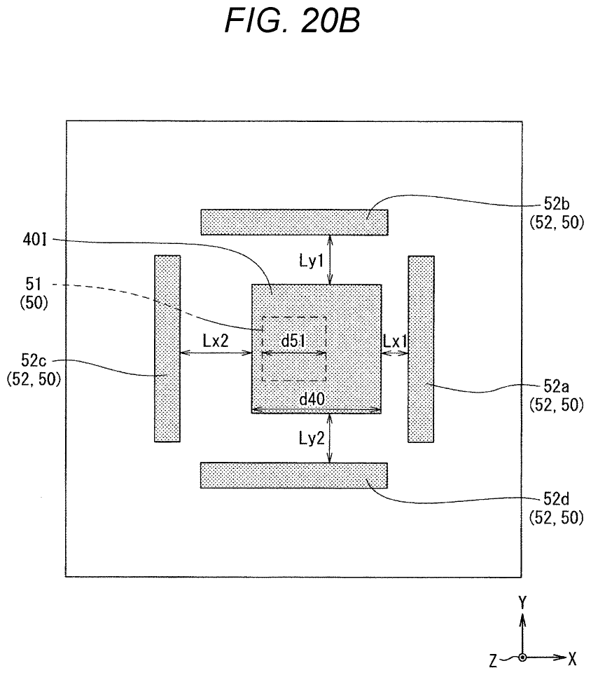

In a state where the second semiconductor chip 30A is bonded to the first semiconductor chip 20 with ideal alignment designed, in the photodetection device 1 according to the first embodiment, a center of a pad electrode 40I and a center of the first sensing electrode 51 described later coincide with each other in plan view, for example, as illustrated in FIG. 6A, but the present technology is not limited thereto. In the photodetection device 1 according to Modification 9 of the first embodiment, as illustrated in FIGS. 20A and 20B, in a state where the second semiconductor chip 30A is bonded to the first semiconductor chip 20 with ideal alignment designed, the center of the pad electrode 40I may not coincide with the center of the first sensing electrode 51 described later. Note that, in the present modification, an example will be described in which the pad electrode 40I is offset in order to achieve the configuration in which the center of the pad electrode 40I does not coincide with the center of the first sensing electrode 51 described later, but the sensing electrode 50 may be offset.

FIG. 20A illustrates an example in which a relative position of the pad electrode 40I with respect to the sensing electrode 50 is offset to the left side of the page. Then, FIG. 20B illustrates an example in which the relative position of the pad electrode 40I with respect to the sensing electrode 50 is offset to the right side of the page. As a result, management values, for example, the management value Lx1 and the management value Lx2 can be set to different values. The offset as described above can be formed by offsetting and exposing the entire mask pattern in a lithography step of a step of forming a layer including the pad electrode 40I. Note that, when bonding the second semiconductor chip 30A to the first semiconductor chip 20, the bonding may simply be performed using a mark of a layer that is not offset.

Effects similar to those of the photodetection device 1 according to the first embodiment described above can also be achieved with the photodetection device 1 according to Modification 9 of the first embodiment.

Furthermore, in the photodetection device 1 according to Modification 9 of the first embodiment, the entire mask pattern may not be offset and exposed, but only a region including the pad electrode 40I may be offset.

Furthermore, the pattern of the pad electrode 40I may be offset in the mask pattern.

### Modification 10

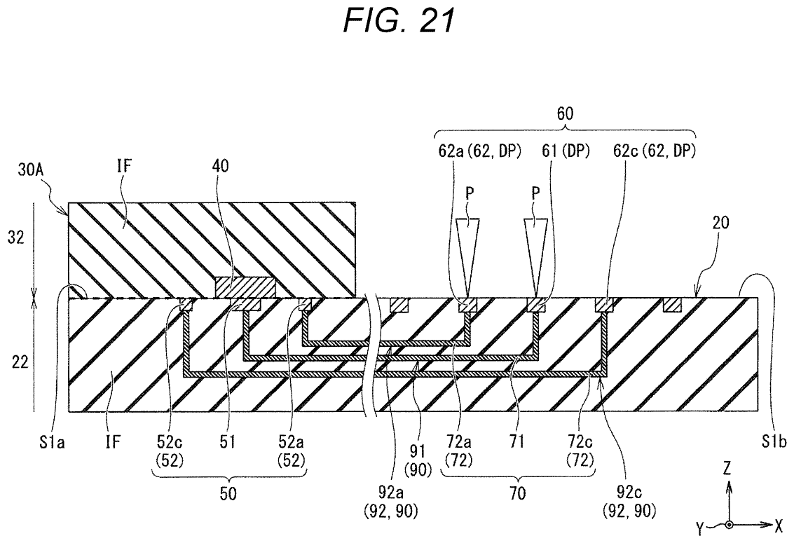

In the photodetection device 1 according to the first embodiment, for example, as illustrated in FIG. 6B, every other dummy pad DP is used as the inspection electrode 60, but the present technology is not limited thereto. In the photodetection device 1 according to Modification 10 of the first embodiment, as illustrated in FIG. 21, the dummy pads DP continuously disposed may be used as the inspection electrode 60.

In the photodetection device 1 according to the first embodiment, an arrangement pitch of the dummy pads DP has been small. Therefore, every other dummy pad DP has been used as the inspection electrode 60 in order to prevent the probe P from being brought into contact with another adjacent inspection electrode 60 when the probe P is brought into contact with one inspection electrode 60.

In this regard, in the photodetection device 1 according to the present modification, since the arrangement pitch of the dummy pads DP is made larger than that in the case of the first embodiment, the continuously disposed dummy pads DP are used as the inspection electrode 60.

Effects similar to those of the photodetection device 1 according to the first embodiment described above can also be achieved with the photodetection device 1 according to Modification 10 of the first embodiment.

### Modification 11

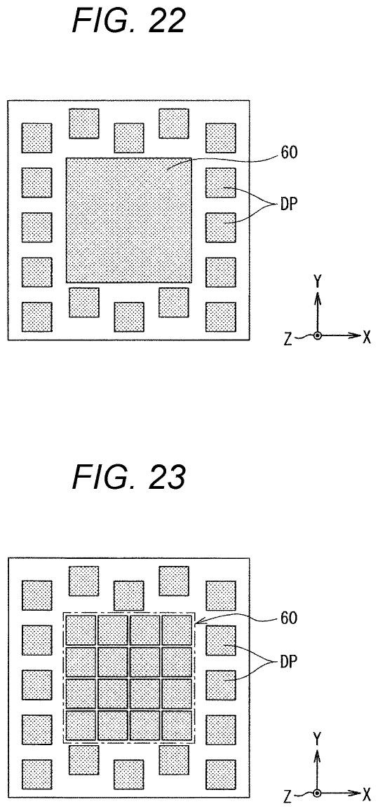

In the photodetection device 1 according to Modification 10 of the first embodiment, the arrangement pitch of the dummy pads DP is widened, but the present technology is not limited thereto. In the photodetection device 1 according to Modification 11 of the first embodiment, as illustrated in FIG. 22, an area of one dummy pad DP used as the inspection electrode 60 may be increased. The inspection electrode 60 has a size of, but not limited to, for example, about 50 μm on one side.

Effects similar to those of the photodetection device 1 according to the first embodiment and the photodetection device 1 according to Modification 10 of the first embodiment described above can be achieved with the photodetection device 1 according to Modification 11 of the first embodiment.

### Modification 12

In the photodetection device 1 according to Modification 11 of the first embodiment, the area of one dummy pad DP is increased, but the present technology is not limited thereto. As illustrated in FIG. 23, in the photodetection device 1 according to Modification 12 of the first embodiment, a plurality of dummy pads DP may be densely arranged to form one large dummy pad group, to be used as the inspection electrode 60. In the dummy pad group, an interval between the dummy pads DP may simply be, but not limited to, for example, 1 μm or less. Furthermore, each dummy pad DP of the dummy pad group is connected to one connection wiring line 70 through a via (not illustrated) or the like. Therefore, the inspection can be performed by bringing the probe P into contact with any dummy pad DP of the dummy pad group.

Effects similar to those of the photodetection device 1 according to the first embodiment described above can also be achieved with the photodetection device 1 according to Modification 12 of the first embodiment.

### Example Application

### <1. Example Application to an Electronic Apparatus>

Next, an electronic apparatus 100 illustrated in FIG. 24 will be described. The electronic apparatus 100 includes a solid-state imaging device 101, an optical lens 102, a shutter device 103, a drive circuit 104, and a signal processing circuit 105. The electronic apparatus 100 is not limited to this, but is an electronic apparatus such as a camera, for example. Furthermore, the electronic apparatus 100 includes the photodetection device 1 described above as the solid-state imaging device 101.

The optical lens (optical system) 102 forms an image of image light (incident light 106) from the subject on the imaging surface of the solid-state imaging device 101. As a result, signal charges are accumulated in the solid-state imaging device 101 over a certain period of time. The shutter device 103 controls a light irradiation period and a light shielding period for the solid-state imaging device 101. The drive circuit 104 supplies a drive signal for controlling a transfer operation of the solid-state imaging device 101 and a shutter operation of the shutter device 103. In accordance with a drive signal (a timing signal) supplied from the drive circuit 104, the solid-state imaging device 101 performs signal transfer. The signal processing circuit 105 performs various kinds of signal processing on a signal (pixel signal) that is output from the solid-state imaging device 101. A video signal subjected to the signal processing is stored into a storage medium such as a memory, or is output to a monitor.

With such a configuration, in the electronic apparatus 100, since misalignment of the bonding between the first semiconductor chip 20 and the second semiconductor chip 30A can be electrically measured in the solid-state imaging device 101, it is possible to contribute to reduction in a misalignment overlooking rate.

Note that the electronic apparatus 100 is not necessarily a camera, and may be some other electronic apparatus. For example, the electronic device 600 may be an imaging device such as a camera module for a mobile device such as a mobile phone.

Furthermore, the electronic apparatus 100 can include, as the solid-state imaging device 101, the photodetection device 1 according to any one of the first embodiment and the modifications thereof, or the photodetection device 1 according to a combination of at least two of the first embodiment and the modifications thereof.

Furthermore, the above-described configurations of the connection pad, the sensing electrode, the inspection electrode, and the connection wiring line are also applicable to a storage circuit such as a memory (not illustrated) formed by bonding multiple semiconductor chips. Furthermore, in a case where the drive circuit 104 and the signal processing circuit 105 are formed by bonding multiple semiconductor chips, the above-described configurations of the connection pad, the sensing electrode, the inspection electrode, and the connection wiring line can also be applied to these circuits.

### <2. Example Application to Mobile Object>

The technology according to the present disclosure (the present technology) can be applied to various products. For example, the technology of the present disclosure may be achieved in the form of a device to be installed on a mobile object of any kind, such as an automobile, an electric vehicle, a hybrid electric vehicle, a motorcycle, a bicycle, a personal mobility, an airplane, a drone, a vessel, or a robot.

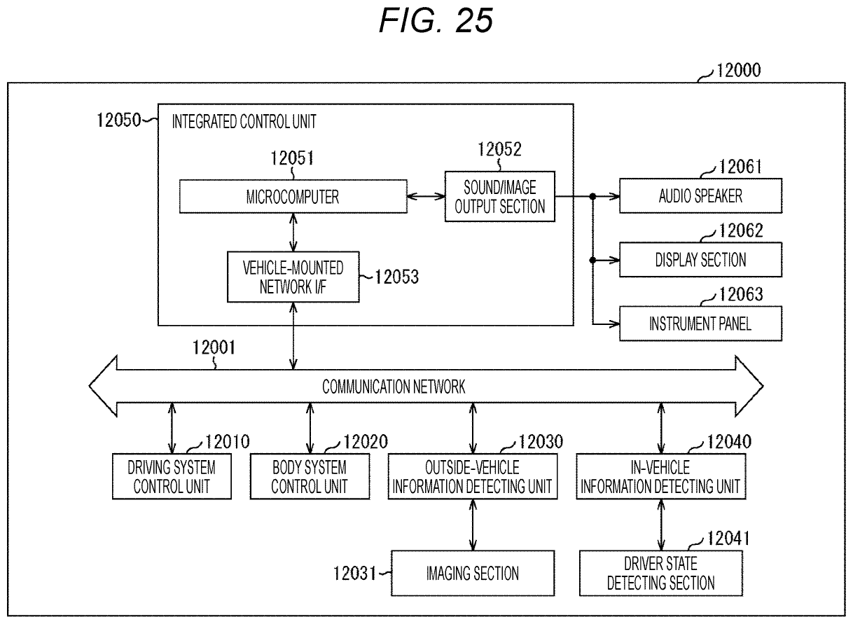

FIG. 25 is a block diagram illustrating an example of schematic configuration of a vehicle control system as an example of a mobile object control system to which the technology according to an embodiment of the present disclosure can be applied.

The vehicle control system 12000 includes a plurality of electronic control units connected to each other via a communication network 12001. In the example illustrated in FIG. 25, the vehicle control system 12000 includes a driving system control unit 12010, a body system control unit 12020, an outside-vehicle information detecting unit 12030, an in-vehicle information detecting unit 12040, and an integrated control unit 12050. Furthermore, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

Furthermore, the microcomputer 12051 can output a control command to the body system control unit 12020 on the basis of the information about the outside of the vehicle acquired by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 25, an audio speaker 12061, a display section 12062, and an instrument panel 12063 are illustrated as the output device. The display section 12062 may, for example, include at least one of an on-board display and a head-up display.

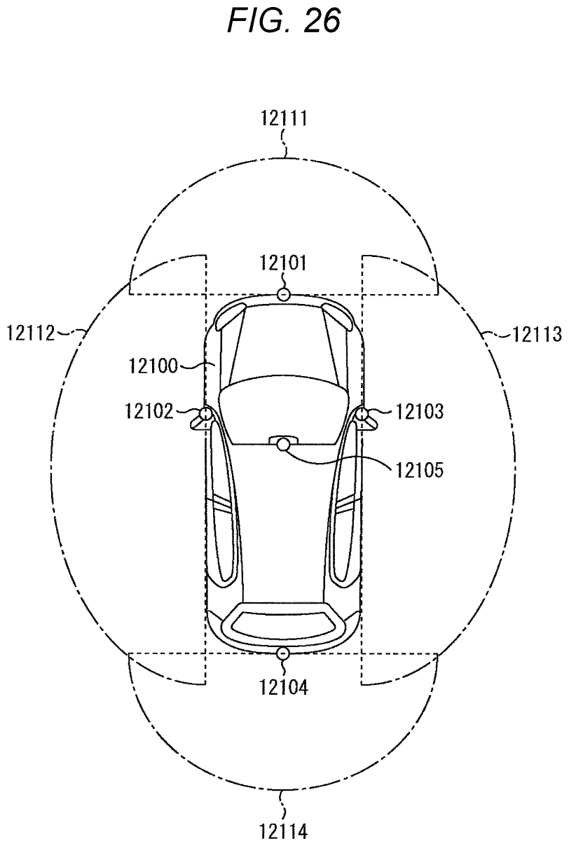

FIG. 26 is a view illustrating an example of the installation position of the imaging section 12031.

In FIG. 26, a vehicle 12100 includes imaging sections 12101, 12102, 12103, 12104, and 12105, as the imaging section 12031.

The imaging sections 12101, 12102, 12103, 12104, 12105 are provided, for example, at positions such as a front nose, a sideview mirror, a rear bumper, a back door, and an upper portion of a windshield in the interior of the vehicle 12100. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The forward images obtained by the imaging sections 12101 and 12105 are used mainly to detect a preceding vehicle, a pedestrian, an obstacle, a traffic signal, a traffic sign, a lane, or the like.

Note that FIG. 26 illustrates an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to the present disclosure can be applied has been described above. Among the configurations described above, the technology according to the present disclosure can be applied to, but not limited to, for example, a semiconductor device formed by bonding multiple semiconductor chips such as the imaging section 12031. By applying the technology related to the imaging section 12031 and the like, it is possible to contribute to reduction of a misalignment overlooking rate.

### Other Embodiments

While the present technology has been described above by way of the first embodiment and the modifications of the embodiments, it should not be understood that the description and drawings constituting a part of this disclosure limit the present technology. Various alternative embodiments, examples, and operation techniques will be apparent to those skilled in the art from this disclosure.

For example, the technical ideas described in the first embodiment and the modifications thereof can be combined with each other.

Furthermore, the present technology can be applied to all kinds of photodetection devices including not only the above-described solid-state imaging device as an image sensor but also a ranging sensor also called a time of flight (ToF) sensor that measures distances, and the like. A ranging sensor is a sensor that emits irradiation light toward an object, detects reflected light that is the irradiation light reflected by a surface of the object, and calculates the distance to the object on the basis of a flight time since the emission of the irradiation light till the reception of the reflected light. As a structure of the distance measuring sensor, the above-described structures of the pad electrode, the sensing electrode, and the connection wiring line can be adopted.

Furthermore, the present technology can be applied to a semiconductor device other than the photodetection device 1. For example, the photoelectric conversion element may not be mounted on the first semiconductor chip 20. The first semiconductor chip 20 may be a storage circuit such as a DRAM, a logic circuit, an AI circuit, or the like.

Furthermore, the materials mentioned as the materials forming the components described above may contain additives, impurities, or the like, for example.

As described above, it is needless to say that the present technology includes various embodiments and the like that are not described herein. Therefore, the technical scope of the present technology is defined only by the matters used to define the inventions disclosed in the claims considered appropriate from the above description.

Furthermore, the effects described herein are mere examples and are not restrictive, and there may be additional effects.

Note that the present technology may also have the following configurations.

(1)

A semiconductor device including:
a first semiconductor chip having one surface as a first joint surface and having a first region and a second region that is a region other than the first region in the first joint surface; and
a second semiconductor chip in which a size in plan view is smaller than a size of the first semiconductor chip, one surface is a second joint surface, and the second joint surface is bonded to the first region, in which
the first semiconductor chip includes a first sensing electrode facing the first region, a second sensing electrode facing the first region and surrounding the first sensing electrode, a first inspection electrode and a second inspection electrode facing the second region, a first connection wiring line electrically connecting the first sensing electrode to the first inspection electrode, and a second connection wiring line electrically connecting the second sensing electrode to the second inspection electrode,
the second semiconductor chip includes a pad electrode facing the second joint surface and connected only to the first sensing electrode out of the first sensing electrode and the second sensing electrode, and
a width of the pad electrode is smaller than a distance between portions of the second sensing electrode opposed to each other with the first sensing electrode interposed in between, and is larger than a distance between the first sensing electrode and the second sensing electrode.
   (2)

The semiconductor device according to (1), in which
the second sensing electrode includes a plurality of second sensing electrode portions electrically separated from each other and arranged along a line surrounding the first sensing electrode, and
the second inspection electrode and the second connection wiring line are provided for each of the second sensing electrode portions.
   (3)

The semiconductor device according to (1), in which the first semiconductor chip includes:
a third sensing electrode facing the first region and surrounding the second sensing electrode;
a third inspection electrode facing the second region; and
a third connection wiring line electrically connecting the third sensing electrode to the third inspection electrode.
   (4)

The semiconductor device according to (3), in which
the third sensing electrode includes a plurality of third sensing electrode portions electrically separated from each other and arranged along a line surrounding the second sensing electrode, and
the third inspection electrode and the third connection wiring line are provided for each of the third sensing electrode portions.
   (5)

The semiconductor device according to any one of (1) to (4), in which
the pad electrode is a polygonal electrode in plan view, and
the second sensing electrode is a band-shaped electrode continuous along an outer shape of a polygonal shape having sides equal in number to a number of sides of the pad electrode.
   (6)

The semiconductor device according to any one of (1) to (5), in which the pad electrode is a rectangular electrode.

(7)

The semiconductor device according to any one of (1) to (5), in which the pad electrode is an octagonal electrode.

(8)

The semiconductor device according to any one of (1) to (5), in which the pad electrode has a re-entrant polygonal shape.

(9)

The semiconductor device according to any one of (5) to (8), in which the first sensing electrode is an electrode having a polygonal shape having sides equal in number to a number of sides as the pad electrode in plan view.

(10)

The semiconductor device according to any one of (1) to (4), in which
the pad electrode is a circular electrode in plan view, and
the second sensing electrode is an annular electrode.
   (11)

The semiconductor device according to (10), in which the first sensing electrode is a circular electrode in plan view.

(12)

The semiconductor device according to any one of (1) to (11), in which a photoelectric conversion element is mounted on the first semiconductor chip.

(13)

The semiconductor device according to (12), in which at least one of a storage circuit, a logic circuit, or an AI circuit is mounted on the second semiconductor chip.

(14)

The semiconductor device according to any one of (1) to (13), in which a plurality of the second semiconductor chips is bonded to the first semiconductor chip.

(15)

A manufacturing method for a semiconductor device, the manufacturing method including:
preparing
a semiconductor wafer including multiple chip regions that are regions to be divided into first semiconductor chips and having one surface as a first joint surface, and
a second semiconductor chip having a size in plan view smaller than a size of each of the chip regions and having one surface as a second joint surface, in which
each of the chip regions includes a first region in the first joint surface, a second region in the first joint surface other than the first region, a first sensing electrode facing the first region, a second sensing electrode facing the first region and surrounding the first sensing electrode, a first inspection electrode and a second inspection electrode facing the second region, a first connection wiring line electrically connecting the first sensing electrode to the first inspection electrode, and a second connection wiring line electrically connecting the second sensing electrode to the second inspection electrode,
the second semiconductor chip includes a pad electrode facing the second joint surface, and
a width of the pad electrode is smaller than a distance between portions of the second sensing electrode opposed to each other with the first sensing electrode interposed in between, and is larger than a distance between the first sensing electrode and the second sensing electrode;
aligning the second semiconductor chip and each of the chip regions such that the pad electrode and the first sensing electrode overlap with each other;
bonding the second joint surface of the second semiconductor chip to the first region of each of the chip regions; and
determining whether or not joint between the second semiconductor chip and each of the chip regions is good on the basis of presence or absence of electrical conduction between the first inspection electrode and the second inspection electrode.
   (16)

An electronic apparatus including: a semiconductor device; and an optical system configured to form an image of image light from a subject on the semiconductor device, in which
the semiconductor device includes:
a first semiconductor chip having one surface as a first joint surface and having a first region and a second region that is a region other than the first region in the first joint surface; and
a second semiconductor chip in which a size in plan view is smaller than a size of the first semiconductor chip, one surface is a second joint surface, and the second joint surface is bonded to the first region,
the first semiconductor chip includes a first sensing electrode facing the first region, a second sensing electrode facing the first region and surrounding the first sensing electrode, a first inspection electrode and a second inspection electrode facing the second region, a first connection wiring line electrically connecting the first sensing electrode to the first inspection electrode, and a second connection wiring line electrically connecting the second sensing electrode to the second inspection electrode,
the second semiconductor chip includes a pad electrode facing the second joint surface and connected only to the first sensing electrode out of the first sensing electrode and the second sensing electrode, and
a width of the pad electrode is smaller than a distance between portions of the second sensing electrode opposed to each other with the first sensing electrode interposed in between, and is larger than a distance between the first sensing electrode and the second sensing electrode.

The scope of the present technology is not limited to the exemplary embodiments illustrated in the drawings and described above, but includes also all embodiments that produce effects equivalent to the effects that the present technology intends to produce. Moreover, the scope of the present technology is not limited to the combinations of the features of the invention defined by the claims, and may be defined by any desired combination of specific features among all the disclosed features.

### REFERENCE SIGNS LIST

1 Photodetection device (semiconductor device)
2 Semiconductor chip
2A Pixel region
3 Pixel
4 Vertical drive circuit
5 Column signal processing circuit
6 Horizontal drive circuit
7 Output circuit
8 Control circuit
13 Logic circuit
14 Bonding pad
15 Readout circuit
20 First semiconductor chip
30, 30A, 30B, 30C Second semiconductor chip
40, 40D, 40E, 40H, 40I Pad electrode
50, 50A, 50B, 50C, 50D, 50E, 50F, 50G, 50H Sensing electrode
51, 51D, 51E, 51H First sensing electrode
52, 52A, 52D, 52E, 52F, 52G, 52H Second sensing electrode
52, 52D, 52F, 52G, 52H Second sensing electrode portion
53, 53C Third sensing electrode
53 Third sensing electrode portion
60 Inspection electrode
61 First inspection electrode
62, 62a, 62c Second inspection electrode
63, 63a, 63c Third inspection electrode
70 Connection wiring line
71 First connection wiring line
72 Second connection wiring line
73 Third connection wiring line
90, 91, 92, 93 Set
100 Electronic apparatus
101 Solid-state imaging device
102 Optical system (optical lens)
103 Shutter device
104 Drive circuit
105 Signal processing circuit
106 Incident light

1. A semiconductor device comprising:
a first semiconductor chip having one surface as a first joint surface and having a first region and a second region that is a region other than the first region in the first joint surface; and
a second semiconductor chip in which a size in plan view is smaller than a size of the first semiconductor chip, one surface is a second joint surface, and the second joint surface is bonded to the first region, wherein
the first semiconductor chip includes a first sensing electrode facing the first region, a second sensing electrode facing the first region and surrounding the first sensing electrode, a first inspection electrode and a second inspection electrode facing the second region, a first connection wiring line electrically connecting the first sensing electrode to the first inspection electrode, and a second connection wiring line electrically connecting the second sensing electrode to the second inspection electrode,
the second semiconductor chip includes a pad electrode facing the second joint surface and connected only to the first sensing electrode out of the first sensing electrode and the second sensing electrode, and
a width of the pad electrode is smaller than a distance between portions of the second sensing electrode opposed to each other with the first sensing electrode interposed in between, and is larger than a distance between the first sensing electrode and the second sensing electrode.

2. The semiconductor device according to claim 1, wherein
the second sensing electrode includes a plurality of second sensing electrode portions electrically separated from each other and arranged along a line surrounding the first sensing electrode, and
the second inspection electrode and the second connection wiring line are provided for each of the second sensing electrode portions.

3. The semiconductor device according to claim 1, wherein
the first semiconductor chip includes:
a third sensing electrode facing the first region and surrounding the second sensing electrode;
a third inspection electrode facing the second region; and
a third connection wiring line electrically connecting the third sensing electrode to the third inspection electrode.

4. The semiconductor device according to claim 3, wherein
the third sensing electrode includes a plurality of third sensing electrode portions electrically separated from each other and arranged along a line surrounding the second sensing electrode, and
the third inspection electrode and the third connection wiring line are provided for each of the third sensing electrode portions.

5. The semiconductor device according to claim 1, wherein
the pad electrode is a polygonal electrode in plan view, and
the second sensing electrode is a band-shaped electrode continuous along an outer shape of a polygonal shape having sides equal in number to a number of sides of the pad electrode.

6. The semiconductor device according to claim 1, wherein the pad electrode is a rectangular electrode.

7. The semiconductor device according to claim 1, wherein the pad electrode is an octagonal electrode.

8. The semiconductor device according to claim 1, wherein the pad electrode has a re-entrant polygonal shape.

9. The semiconductor device according to claim 5, wherein the first sensing electrode is an electrode having a polygonal shape having sides equal in number to a number of sides as the pad electrode in plan view.

10. The semiconductor device according to claim 1, wherein
the pad electrode is a circular electrode in plan view, and
the second sensing electrode is an annular electrode.

11. The semiconductor device according to claim 10, wherein the first sensing electrode is a circular electrode in plan view.

12. The semiconductor device according to claim 1, wherein a photoelectric conversion element is mounted on the first semiconductor chip.

13. The semiconductor device according to claim 12, wherein at least one of a storage circuit, a logic circuit, or an AI circuit is mounted on the second semiconductor chip.

14. The semiconductor device according to claim 1, wherein a plurality of the second semiconductor chips is bonded to the first semiconductor chip.

15. A manufacturing method for a semiconductor device, the manufacturing method comprising:
preparing
a semiconductor wafer including multiple chip regions that are regions to be divided into first semiconductor chips and having one surface as a first joint surface, and
a second semiconductor chip having a size in plan view smaller than a size of each of the chip regions and having one surface as a second joint surface, in which
each of the chip regions includes a first region in the first joint surface, a second region in the first joint surface other than the first region, a first sensing electrode facing the first region, a second sensing electrode facing the first region and surrounding the first sensing electrode, a first inspection electrode and a second inspection electrode facing the second region, a first connection wiring line electrically connecting the first sensing electrode to the first inspection electrode, and a second connection wiring line electrically connecting the second sensing electrode to the second inspection electrode,
the second semiconductor chip includes a pad electrode facing the second joint surface, and
a width of the pad electrode is smaller than a distance between portions of the second sensing electrode opposed to each other with the first sensing electrode interposed in between, and is larger than a distance between the first sensing electrode and the second sensing electrode;
aligning the second semiconductor chip and each of the chip regions such that the pad electrode and the first sensing electrode overlap with each other;
bonding the second joint surface of the second semiconductor chip to the first region of each of the chip regions; and
determining whether or not joint between the second semiconductor chip and each of the chip regions is good on a basis of presence or absence of electrical conduction between the first inspection electrode and the second inspection electrode.

16. An electronic apparatus comprising: a semiconductor device; and an optical system configured to form an image of image light from a subject on the semiconductor device, wherein
the semiconductor device includes:
a first semiconductor chip having one surface as a first joint surface and having a first region and a second region that is a region other than the first region in the first joint surface; and
a second semiconductor chip in which a size in plan view is smaller than a size of the first semiconductor chip, one surface is a second joint surface, and the second joint surface is bonded to the first region,
the first semiconductor chip includes a first sensing electrode facing the first region, a second sensing electrode facing the first region and surrounding the first sensing electrode, a first inspection electrode and a second inspection electrode facing the second region, a first connection wiring line electrically connecting the first sensing electrode to the first inspection electrode, and a second connection wiring line electrically connecting the second sensing electrode to the second inspection electrode,
the second semiconductor chip includes a pad electrode facing the second joint surface and connected only to the first sensing electrode out of the first sensing electrode and the second sensing electrode, and
a width of the pad electrode is smaller than a distance between portions of the second sensing electrode opposed to each other with the first sensing electrode interposed in between, and is larger than a distance between the first sensing electrode and the second sensing electrode.
